(19) United States
(12) Patent Application Publication
(10) Pub. No.: US 2025/0331179 A1
(43) Pub. Date: Oct. 23, 2025

(54) SEMICONDUCTOR DEVICE, FABRICATION METHOD AND MEMORY SYSTEM

(71) Applicant: YANGTZE MEMORY TECHNOLOGIES CO., LTD., Wuhan (CN)

(72) Inventors: Wei Yuan, Wuhan (CN); Kun Zhang, Wuhan (CN); Yuhui Han, Wuhan (CN)

(21) Appl. No.: 18/821,743

(22) Filed: Aug. 30, 2024

(30) Foreign Application Priority Data
Apr. 22, 2024 (CN) 202410488443.3

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

According to one aspect of the present disclosure, a semiconductor device is provided. The semiconductor device may include a stack structure comprising gate layers and first dielectric layers stacked alternatively in a first direction. The semiconductor device may include a gate line isolation structure extending in the stack structure along a second direction intersecting the first direction and comprising a first section and a second section arranged with an interval in the second direction. The semiconductor device may include a first spacer structure and a second spacer structure, the first spacer structure and the second spacer structure may both be located between the first section and the second section, and the second spacer structure may surround the first spacer structure.

### CROSS-REFERENCE TO RELATED APPLICATIONS

This application claims the benefit of priority to Chinese Application No. 202410488443.3, filed on Apr. 22, 2024, which is incorporated herein by reference in its entirety.

### TECHNICAL FIELD

The present disclosure relates to the field of semiconductor design and fabrication, and more particularly to a semiconductor device, a method of fabricating semiconductor device and a memory system.

### BACKGROUND

Memory is one of important storage components in an electronic system. Considering a three-dimensional memory as an example, a semiconductor device may include a stack structure and a gate line isolation structure, where the stack structure is formed by stacking gate layers and dielectric layers alternatively and the gate line isolation structure extends in the stack structure along a direction intersecting the stacking direction of the stack structure.

With the rapid development of semiconductor technology, how to optimize comprehensive performance of semiconductor device while simplifying fabrication process of the semiconductor device and reducing manufacturing cost of the semiconductor device is an important research direction in the industry.

### SUMMARY

According to one aspect of the present disclosure, a semiconductor device is provided. The semiconductor device may include a stack structure including gate layers and first dielectric layers stacked alternatively in a first direction. The semiconductor device may include a gate line isolation structure extending in the stack structure along a second direction intersecting the first direction and including a first section and a second section arranged with an interval in the second direction. The semiconductor device may include a first spacer structure and a second spacer structure, the first spacer structure and the second spacer structure may both be located between the first section and the second section, and the second spacer structure may surround the first spacer structure.

In some implementations, the semiconductor device may include a channel structure extending in the stack structure in the first direction. In some implementations, the channel structure may include a functional layer and a channel layer on a surface of the functional layer. in some implementations, the first spacer structure may have a same layer structure as the channel structure.

In some implementations, the second spacer structure may include a plurality of isolation layers. In some implementations, the isolation layers and the first dielectric layers may be stacked alternatively in the first direction and the isolation layer is disposed in a same layer as the gate layer.

In some implementations, the second spacer structure may further include an isolation post. In some implementations, the isolation post may extend in the first direction and may include a same insulating dielectric material as the isolation layer.

In some implementations, the first spacer structure may include a first separating structure and a second separating structure. In some implementations, the first separating structure may be closer to the first section in the second direction than the second separating structure. In some implementations, the second separating structure may be closer to the second section in the second direction than the first separating structure.

In some implementations, a size of the first spacer structure in the second direction may be greater than a size of the first spacer structure in a third direction. In some implementations, the third direction may intersect both the first direction and the second direction.

In some implementations, the first spacer structure may include a plurality of post structures arranged with intervals in the second direction.

In some implementations, at least one surface of the gate line isolation structure may include a curved surface including at least one of a concave surface and a convex surface.

In some implementations, the stack structure may include an array region and a connection region arranged in the second direction. In some implementations, the gate layer may include a first portion in the array region and a second portion in the connection region. In some implementations, a surface of the first portion facing the connection region may include a curved surface including at least one of a concave surface and a convex surface.

In some implementations, the stack structure may further include a second dielectric layer disposed in a same layer as the gate layer. In some implementations, the first dielectric layer and the second dielectric layer may include different insulating dielectric materials.

In some implementations, a size of the first section or the second section in a third direction may be less than or equal to a size of the first spacer structure in the third direction. In some implementations, the third direction may intersect the first direction and the second direction.

In some implementations, an extension size D of the second spacer structure in a direction intersecting the first direction may satisfy 400 nm≤D≤1500 nm.

In some implementations, the stack structure may include an array region and a connection region arranged in the second direction. In some implementations, the first spacer structure and the second spacer structure may both be located in a first sub-region of the array region close to the connection region.

According to another aspect of the present disclosure, a semiconductor device is provided. The semiconductor device may include a stack structure including gate layers and first dielectric layers stacked alternatively in a first direction. The semiconductor device may include a first channel structure and a second channel structure both extending in the stack structure in the first direction. The semiconductor device may include a gate line isolation structure extending in the stack structure along a second direction intersecting the first direction and including a first section and a second section arranged with an interval. The semiconductor device may include a spacer structure between the first section and the second section. The spacer structure and a plurality of the second channel structures may be arranged in a third direction, and the third direction may intersect both the first direction and the second direction. A size of the second channel structure may be greater than a size of the first channel structure in a direction intersecting the first direction.

In some implementations, a part of the plurality of the second channel structures may be located on a side of the spacer structure in the third direction, others of the plurality of the second channel structures are located in the spacer structure.

In some implementations, an extension size D of the spacer structure in a direction intersecting the first direction may satisfy 400 nm≤D≤1500 nm.

In some implementations, the spacer structure may include a plurality of isolation layers. In some implementations, the isolation layers and the first dielectric layers may be stacked alternatively in the first direction and the isolation layer is disposed in a same layer as the gate layer.

In some implementations, the spacer structure may further include an isolation post. In some implementations, the isolation post may extend in the first direction and includes a same insulating dielectric material as the isolation layer.

In some implementations, in a direction intersecting the first direction, a size d1 of the first channel structure and a size d2 of the second channel structure may satisfy: 1.1d1≤d2.

In some implementations, in a direction intersecting the first direction, a size d2 of the second channel may satisfy 110 nm<d2≤150 nm.

In some implementations, a size of the first section in the third direction may be less than or equal to a size of the second section in the third direction. In some implementations, the third direction may intersect the first direction and the second direction.

In some implementations, a size b1 of the first section in the third direction and a size b2 of the second section in the third direction may satisfy 1.1b1≤b2.

In some implementations, a size b2 of the second section in the third direction may satisfy 300 nm<b2≤900 nm.

In some implementations, the stack structure may include an array region and a connection region arranged in a second direction intersecting the first direction. In some implementations, the gate layer may include a first portion in the array region and a second portion in the connection region. In some implementations, a surface of the first portion facing the connection region may include a curved surface including at least one of a concave surface and a convex surface.

In some implementations, the stack structure may further include a second dielectric layer disposed in a same layer as the gate layer. In some implementations, the first dielectric layer and the second dielectric layer may include different insulating dielectric materials.

In some implementations, the spacer structure may include a first spacer structure and a second spacer structure surrounding the first spacer structure.

In some implementations, the first spacer structure may include a first separating structure and a second separating structure. In some implementations, the first separating structure may be closer to the first section in the second direction than the second separating structure. In some implementations, the second separating structure may be closer to the second section in the second direction than the first separating structure.

In some implementations, a size of the first spacer structure in the second direction may be greater than a size of the first spacer structure in the third direction. In some implementations, the third direction may intersect both the first direction and the second direction.

In some implementations, the first channel structure and the second channel structure each may include a functional layer and a channel layer on a surface of the functional layer. In some implementations, the first spacer structure may have a same layer structure as the channel structure.

In some implementations, at least one surface of the gate line isolation structure may include a curved surface including at least one of a concave surface and a convex surface.

According to a further aspect of the present disclosure, a method of fabricating a semiconductor device is provided. The method may include
stacking gate sacrificial layers and first dielectric layers alternatively in a first direction to form a stack structure;
forming a first slit and a second slit spaced apart from each other in the stack structure, both the first slit and the second slit extending in a second direction intersecting the first direction;
forming a first spacer structure and a second spacer structure surrounding the first spacer structure between the first slit and the second slit; and
removing part of the gate sacrificial layer via the first slit and the second slit to form a gate layer.

In some implementations, forming the second spacer structure may include forming a first opening and a second opening between the first slit and the second slit. In some implementations the first opening and the second opening may be arranged with an interval in the second direction. In some implementations, forming the second spacer structure may include removing part of the gate sacrificial layer via the second opening to form a separating void. In some implementations, forming the second spacer structure may include filling the second opening and the separating void with an insulating dielectric material to form the second spacer structure.

In some implementations, the semiconductor device may include a channel structure. In some implementations, the method may further include forming a channel hole and the first opening extending in the stack structure in the first direction. In some implementations, the method may further include forming a functional layer in the channel hole and the first opening and forming a channel layer on a surface of the functional layer. In some implementations, parts of the functional layer and the channel layer that are filled in the first opening may form the first spacer structure.

In some implementations, the first opening may include at least one of a hole extending in the first direction and a trench extending in the second direction.

In some implementations, forming the first slit and the second slit may include forming first holes penetrating through the stack structure in the first direction. In some implementations, a plurality of the first holes may be arranged with intervals in the second direction. In some implementations, forming the first slit and the second slit may include removing at least parts of the stack structure located between the first holes adjacent in the second direction to form the first slit and the second slit.

In some implementations, the semiconductor device may further include a channel structure. In some implementations, forming the channel structure may include forming a channel hole extending in the stack structure in the first direction. In some implementations, forming the channel structure may include forming a functional layer in the channel hole and forming a channel layer on a surface of the functional layer. In some implementations, the channel hole may be formed in a process of forming the first hole.

In some implementations, the removing part of the gate sacrificial layer via the first slit and the second slit to form a gate layer may include filling the second slit with a first sacrificial layer. In some implementations, the removing part of the gate sacrificial layer via the first slit and the second slit to form a gate layer may include removing part of the gate sacrificial layer via the first slit to form a first void. In some implementations, the removing part of the gate sacrificial layer via the first slit and the second slit to form a gate layer may include filling the first void and the first slit with a second sacrificial layer. In some implementations, the removing part of the gate sacrificial layer via the first slit and the second slit to form a gate layer may include removing the first sacrificial layer and removing part of the gate sacrificial layer via the second slit to form a second void communicating with the first void. In some implementations, the removing part of the gate sacrificial layer via the first slit and the second slit to form a gate layer may include removing the second sacrificial layer and forming the gate layer in the first void and the second void.

According to still a further aspect of the present disclosure, a method of fabricating a semiconductor device is provided. The method may include stacking gate sacrificial layers and first dielectric layers alternatively in a first direction to form a stack structure. The method may include forming a first channel structure and a second channel structure extending in the stack structure in the first direction. In a direction intersecting the first direction, a size of the second channel structure may be greater than a size of the first channel structure. The method may include forming a first slit and a second slit spaced apart from each other in the stack structure. Both the first slit and the second slit may extend in a second direction intersecting the first direction. The method may include forming a spacer structure between the first slit and the second slit. The spacer structure and a plurality of the second channel structures may be arranged in a third direction. The third direction may intersect both the first direction and the second direction. The method may include removing part of the gate sacrificial layer via the first slit and the second slit to form a gate layer.

In some implementations, forming the first channel structure and the second channel structure may include forming a first channel hole and a second channel hole. In some implementations, both the first channel hole and the second channel hole may extend in the stack structure in the first direction, and in a direction intersecting the first direction, a size of the second channel hole may be greater than a size of the first channel hole. In some implementations, forming the first channel structure and the second channel structure may include forming a functional layer in the first channel hole and the second channel hole, respectively, and forming a channel layer on a surface of the functional layer.

In some implementations, forming the first slit and the second slit may include forming first holes penetrating through the stack structure in the first direction. In some implementations, a plurality of the first holes may be arranged with intervals in the second direction. In some implementations, forming the first slit and the second slit may include removing at least parts of the stack structure located between the first holes adjacent in the second direction to form the first slit and the second slit.

In some implementations, in a direction intersecting the first direction, a size of the second channel hole may be equal to a size of the first hole.

In some implementations, the first channel hole and the second channel hole may be formed in a process of forming the first hole.

In some implementations, forming the spacer structure may include forming a second opening located between the first slit and the second slit. In some implementations, forming the spacer structure may include removing part of the gate sacrificial layer via the second opening to form a separating void. In some implementations, forming the spacer structure may include filling the second opening and the separating void with an insulating dielectric material to form the spacer structure.

In some implementations, forming the second opening may include forming second holes penetrating through the stack structure in the first direction. In some implementations, a plurality of the second holes may be arranged with intervals in the second direction. In some implementations, forming the second opening may include removing at least parts of the stack structure located between the second holes adjacent in the second direction to form the second opening.

According to yet another aspect of the present disclosure, a memory system is provided. The memory system my include at least one semiconductor device. The at least one semiconductor device may include a stack structure including gate layers and first dielectric layers stacked alternatively in a first direction. The at least one semiconductor device may include a gate line isolation structure extending in the stack structure along a second direction intersecting the first direction and including a first section and a second section arranged with an interval in the second direction. The at least one semiconductor device may further include a first spacer structure and a second spacer structure. The first spacer structure and the second spacer structure may both be located between the first section. The second section and the second spacer structure may surround the first spacer structure. The memory system may include a controller coupled with the semiconductor device and configured to control the semiconductor device to store data.

According to yet a further aspect of the present disclosure, a memory system is provided. The memory system may include at least one semiconductor device. The at least one semiconductor device may include a stack structure including gate layers and first dielectric layers stacked alternatively in a first direction. The at least one semiconductor device may include a first channel structure and a second channel structure both extending in the stack structure in the first direction. The at least one semiconductor device may include a gate line isolation structure extending in the stack structure along a second direction intersecting the first direction and including a first section and a second section arranged with an interval. The at least one semiconductor device may include a spacer structure between the first section and the second section. The spacer structure and a plurality of the second channel structures may be arranged in a third direction. The third direction may intersect both the first direction and the second direction. A size of the second channel structure may be greater than a size of the first channel structure in a direction intersecting the first direction. The memory system may include a controller coupled with the semiconductor device and configured to control the semiconductor device to store data.

### BRIEF DESCRIPTION OF THE DRAWINGS

Through reading the detailed description of non-limiting implementations made with reference to the following figures, other features, purposes and beneficial effects of the present disclosure will become more apparent. In the drawings,

FIG. 1 is a top view of a semiconductor device, according to an implementation of the present disclosure;

FIG. 2 is a top view of a semiconductor device, according to another implementation of the present disclosure;

FIG. 3 is a cross-sectional diagram of the semiconductor device shown in FIG. 1 taken along line A-A′;

FIG. 4 is a cross-sectional diagram of a semiconductor device, according to an implementation of the present disclosure;

FIG. 5 is a top view of a gate line isolation structure, according to an implementation of the present disclosure;

FIG. 6 is a top view of a semiconductor device, according to an implementation of the present disclosure;

FIG. 7 is a top view of a semiconductor device, according to yet another implementation of the present disclosure;

FIG. 8 is a cross-sectional diagram of the semiconductor device shown in FIG. 7 taken along line B-B′;

FIG. 9 is a cross-sectional diagram of a semiconductor device, according to yet another implementation of the present disclosure;

FIG. 10 is a top view of a semiconductor device, according to yet another implementation of the present disclosure;

FIG. 11 is a cross-sectional diagram of the semiconductor device shown in FIG. 10 taken along line C-C′;

FIG. 12 is a cross-sectional diagram of the semiconductor device shown in FIG. 10 taken along line E-E′;

FIG. 13 is a cross-sectional diagram of a semiconductor device, according to yet another implementation of the present disclosure;

FIG. 14 is a flow chart of a method of fabricating a semiconductor device, according to an implementation of the present disclosure;

FIGS. 15-31 are process diagrams of a method of fabricating a semiconductor device, according to an implementation of the present disclosure respectively;

FIG. 32 is a flow chart of a method of fabricating a semiconductor device, according to another implementation of the present disclosure;

FIGS. 33-41 are process diagrams of a method of fabricating a semiconductor device, according to another implementation of the present disclosure respectively; and

FIG. 42 is a structure diagram of a memory system, according to an implementation of the present disclosure.

### DETAILED DESCRIPTION

The present disclosure will be described in detail below with reference to drawings. Example implementations mentioned herein are only used to explain the present disclosure rather than limiting the scope of the present disclosure. Throughout the specification, identical reference numerals refer to identical elements.

In the figures, thicknesses, dimensions and shapes of components have been somewhat adjusted for easy illustration. The figures are only examples and not strictly drawn to scale. As used herein, terms “approximate”, “about” and the like indicate approximation instead of degrees and are intended to mean inherent variations in measurement values or calculated values, which can be appreciated by those of ordinary skills in the art.

It will also be appreciated that the expression “and/or” covers any and all combinations of one or more of the listed items. As used herein, expressions such as “include”, “comprise”, “have” and/or “contain” are not exclusive but open, i.e. they indicate existence of the stated feature, element and/or component, but will not exclude existence or addition of one or more other features, elements, components and/or any combinations thereof. Furthermore, when the expression “at least one of” precedes a list of features, it modifies all the listed features instead of any individual ones. As used in the description of an implementation of the present disclosure, the term “may” is used to indicate “one or more implementations of the present disclosure”. Also, the term “example” means to be exemplary or illustrative.

Moreover, as used in the application, the term “connect”, “cover” and/or “form on” may indicate direct or indirect contact between corresponding components, unless it is otherwise defined or exact meaning can be derived from its context.

All the terms (including engineering terms and scientific and technical terms) used herein have the same meanings as those commonly understood by those of ordinary skills in the art, unless otherwise specified. Furthermore, the terms defined in common dictionaries should be interpreted to have the meanings consistent with their contexts in pertinent arts and should not be interpreted too ideally or formally, unless otherwise specified explicitly in the application.

It is to be noted that implementations of the present disclosure and features thereof may be combined where there are no conflicts. Furthermore, operations contained in a method described in the present disclosure may not necessarily be performed in the described order and instead may be performed in any other order or in parallel, unless there is an explicit definition or any conflict with the context. The present disclosure will be described in detail hereafter in connection with implementations with reference to accompanying drawings.

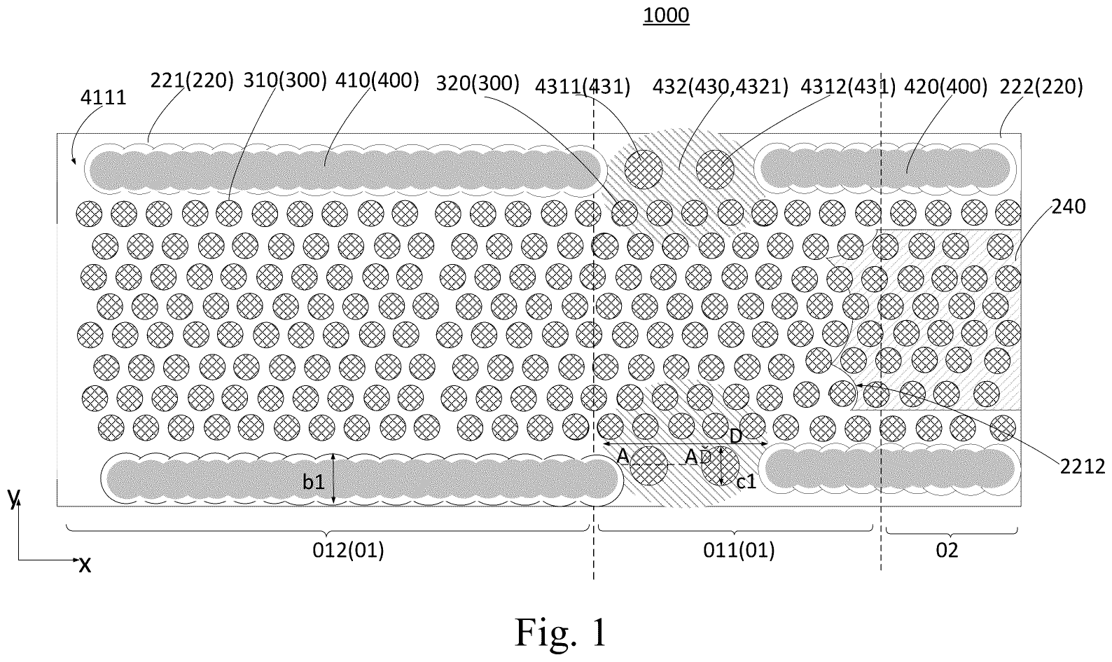

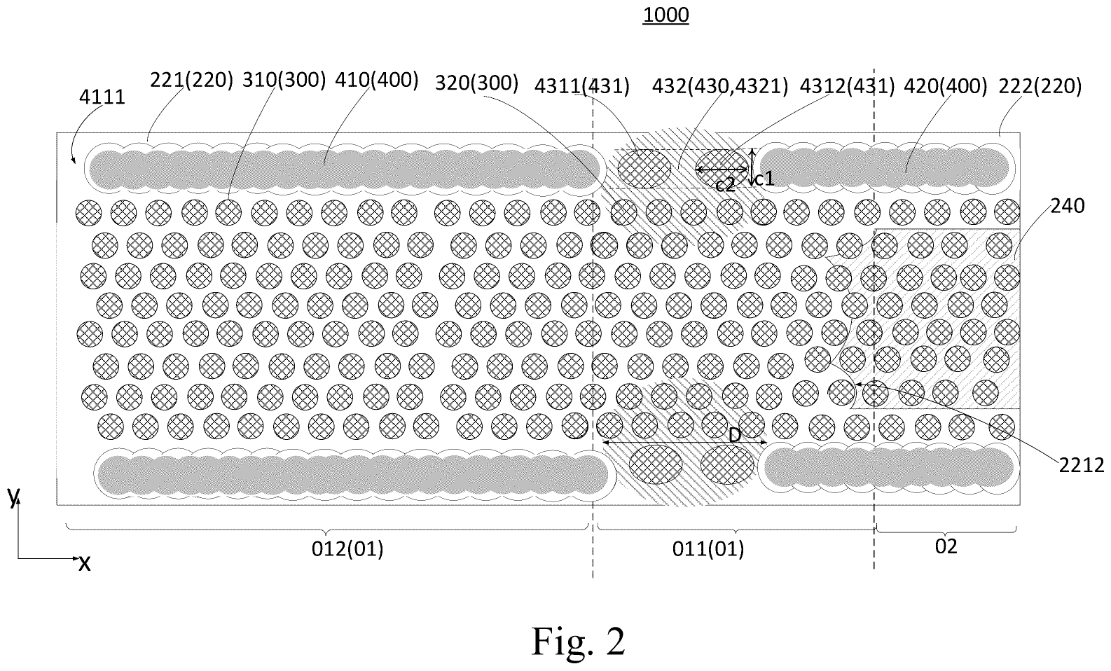

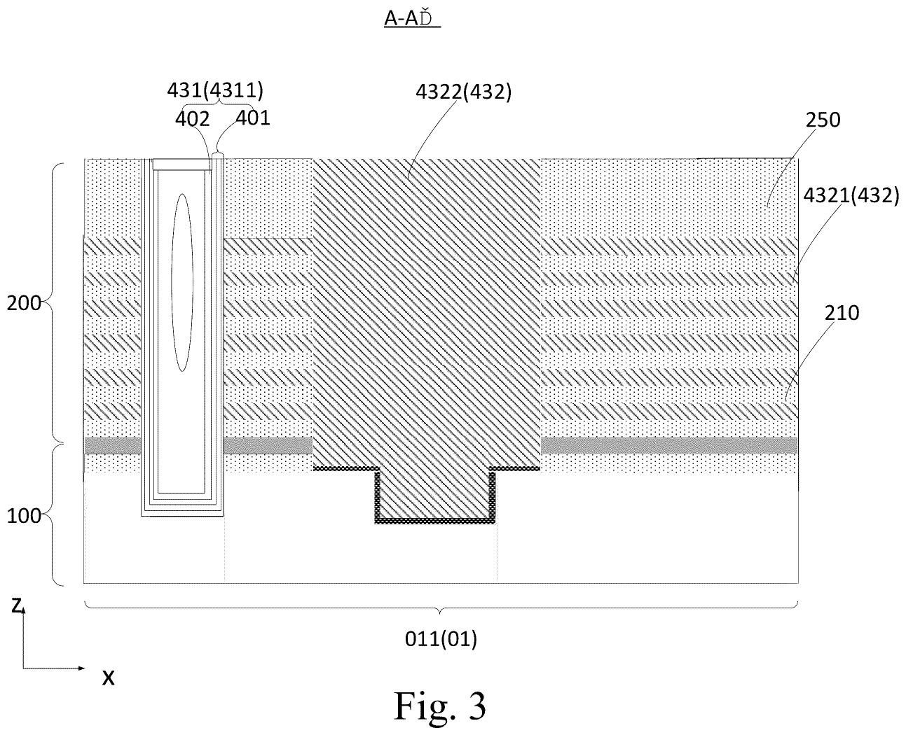

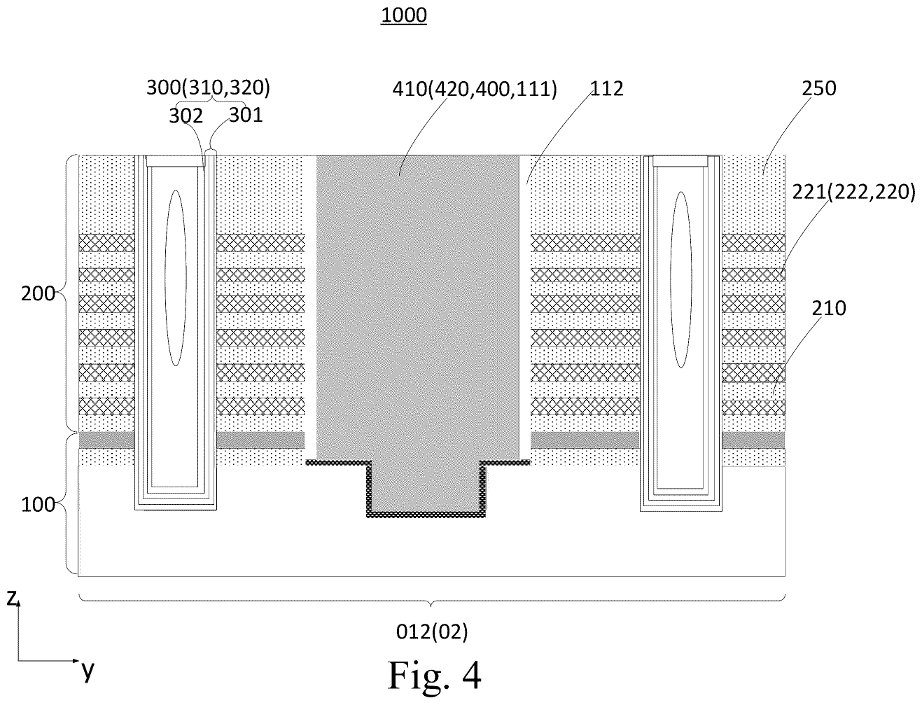

FIG. 1 is a top view of a semiconductor device 1000, according to an implementation of the present disclosure. FIG. 2 is a top view of a semiconductor device 1000, according to another implementation of the present disclosure. FIG. 3 is a cross-sectional diagram of the semiconductor device 1000 shown in FIG. 1 taken along line A-A′. FIG. 4 is a cross-sectional diagram of a semiconductor device 1000, according to an implementation of the present disclosure.

As shown in FIGS. 1-4, an aspect of the present disclosure provides a semiconductor device 1000 that may include a stack structure 200, a gate line isolation structure 400, a first spacer structure 431 and a second spacer structure 432. The stack structure 200 includes first dielectric layers 210 and gate layers 220 stacked alternatively in a first direction (e.g., z-direction). The gate line isolation structure 400 extends in the stack structure 200 along a second direction (e.g., x-direction) intersecting the z-direction and includes a first section 410 and a second section 420 arranged with an interval in x-direction. The first spacer structure 431 and the second spacer structure 432 are both located between the first section 410 and the second section 420 and the second spacer structure 432 surrounds the first spacer structure 431.

It is to be noted that in order to facilitate observing shapes and locations of structures other than the gate layer 220 in the semiconductor device 1000, only the profile of the gate layer 220 is illustrated with black lines in FIGS. 1 and 2 rather than filling it.

The gate layer of the stack structure provided in implementations of the present disclosure may be fabricated with gate last process. For example, a gate sacrificial layer is formed in advance. In the process of etching off the gate sacrificial layer with e.g., wet etching, the etchant and chemical precursor are brought into contact with the gate sacrificial layer and in turn remove partial gate sacrificial layer to form the gate layer by means of gate line slits formed while forming the gate line isolation structure, such as the first gate line slit and the second gate line slit. The first spacer structure and the second spacer structure divide the gate line isolation structure into the first section and the second section; and similarly the first spacer structure and the second spacer structure separate the first slit and the second slit in the process of fabricating the semiconductor device, which can reduce the case in which excess etch solution flows into other structures that have been formed in the semiconductor intermediate via gate line slits in the process of removing gate sacrificial layer with gate last process while fabricating the semiconductor device, thereby improving comprehensive performance of the semiconductor device.

Moreover, the semiconductor device further includes a channel structure. The second spacer structure surrounds the first spacer structure, which may improve the stress of the part of the stack structure at which the first spacer structure and the second spacer structure are located, reduce the cases in which topology of multiple channel structures corresponding to the second spacer structure surrounds the first spacer structure shift, thereby improving the uniformity and consistency of the multiple channel structures and improving the comprehensive performance of semiconductor device.

In particular, as shown in FIG. 4, the stack structure 200 may be disposed on a side of the substrate 100. The material for the substrate 100 may include semiconductor materials which may include, but not limited to elementary semiconductor material such as silicon, germanium, III-V compound semiconductor material, II-VI compound semiconductor material, organic semiconductors material or other semiconductor material known in the art. Illustratively, the substrate 100 may include a silicon substrate. In addition, the substrate 100 may be a composite structure. For example, the composite structure may include a layer structure connected with the channel structure 300, where the channel structure 300 will be described in detail below with reference to drawings.

Optionally, as shown in FIGS. 1 and 4, the stack structure 200 includes an array region 01 and connection region 02 arranged adjacently in x-direction, where the array region 01 may include a first sub-region 011 and a second sub-region 012 adjacent in x-direction, and the first sub-region 011 is closer to the connection region 02 than the second sub-region 012. The connection region 02 may include contact structures (not shown) connected with gate layers 220 such that gate layers are connected with external circuits (not shown) through the contact structures.

As an option, the gate layer 220 may include a conductive material, for example, any one or combination of tungsten (W), cobalt (Co), copper (Cu), aluminum (Al), doped crystalline silicon or silicide. The first dielectric layer 210 may function as an isolation stack layer, including, but not limited to insulating dielectric material layers such as silicon oxide layer.

In addition, the stack structure 200 further includes a plurality of second dielectric layers 240. The second dielectric layer 240 and the first dielectric layer 210 are two different insulating dielectric layers. For example, the second dielectric layer 240 may include, but not limited to insulating dielectric layer such as silicon nitride layer. Furthermore, the plurality of second dielectric layers 240 and the plurality of gate layers 220 may have the same stacking height. Optionally, the number of layers of the stack structure 200 is not limited to that shown in the figure, and can be otherwise configured as required, for example, 32, 64, 128 etc.

In other words, the stack structure 200 may include first dielectric layers 210 and composite layers stacked alternatively, where the composite layer may include a gate layer 220 and a second dielectric layer 240 disposed in the same layer. For example, the gate layer 220 and the second dielectric layer 240 may be connected with each other in the x-y plane intersecting z-direction. The gate layer 220 extends to the connection region 02 from the array region 01 of the stack structure 200 in x-direction and is connected with the second dielectric layer 240 disposed in the same layer, where the second dielectric layer 240 is located in the connection region 02.

Optionally, the gate layer 220 may include a first portion 221 in the array region 01 and a second portion 222 in the connection region 02 which are connected with each other. Furthermore, the surface 2212 of the first portion 221 facing the connection region 02 includes a curved surface including at least one of concave surface and convex surface. This can release the local stress of the semiconductor device and improve the stability of semiconductor device.

Furthermore, as shown in FIGS. 3 and 4, the stack structure 200 may further include a dielectric covering layer 250 that may be fabricated with the same material as the first dielectric layer 210. Optionally, a size of the dielectric covering layer 250 in z-direction may be greater than a size of the first dielectric layer 210 or the gate layer 220 in z-direction.

In addition, referring to FIGS. 1, 3 and 4, in some implementations of the present disclosure, the semiconductor device 1000 further includes a channel structure 300 extending in z-direction in the stack structure 200, where the channel structure 300 includes a functional layer 301 and a channel layer 302 on the surface of the functional layer 301. For example, the channel structure 300 may include a functional layer 301 on the inner wall of a first channel hole (not shown) and a channel layer 302 on the surface of the functional layer 301. The functional layer 301 may include a blocking layer, a charge trapping layer and a tunneling layer disposed in turn on inner wall of the channel hole. In some implementations, the functional layer 301 may include an oxide-nitride-oxide (ONO) structure. However, in some other implementations, the functional layer 301 may have a structure different from ONO configuration. The channel layer 302 may be on the surface of the tunneling layer and can carry required charges (electrons or holes). The channel layer 302 may be fabricated from semiconductor material such as poly-crystalline silicon or single crystalline silicon and may have conductive impurities. Furthermore, the channel structure 300 may further include a channel filling dielectric layer filled in the remained space in the channel hole after forming the functional layer 301 and the channel layer 302. The channel filling dielectric layer includes an insulating dielectric material layer such as silicon oxide layer.

Optionally, the first spacer structure 431 may include the same layer structure as the channel structure 300. In other words, the first spacer structure 431 may include a first layer 401 and a second layer 402 on the surface of the first layer 401. For example, the first layer 401 may have the same layer structure as the functional layer 301 and may include an oxide-nitride-oxide (ONO) structure. However, in some other implementations, the first layer 401 may also have a structure different from ONO configuration. The second layer 402 and the channel layer 302 may have the same layer structure. The second layer 402 may be fabricated from semiconductor material such as poly-crystalline silicon or single crystalline silicon and may have conductive impurities. Furthermore, the first spacer structure 431 may also include a third layer having the same layer structure as the channel filling dielectric layer. The third layer includes an insulating dielectric material layer such as silicon oxide layer.

Furthermore, the first spacer structure 431 may also be formed in the same process as the channel structure 300 to simplify the fabrication process of semiconductor device and reduce the fabrication costs of semiconductor device.

Optionally, the channel structure 300 includes a first channel structure 310, a second channel structure 320 and a third channel structure.

For instance, the stack structure 200 includes an array region 01 and connection region 02 arranged adjacently in x-direction, where the array region 01 includes a first sub-region 011 and a second sub-region 012 adjacent in x-direction, and the first sub-region 011 is closer to the connection region 02 than the second sub-region 012. The plurality of first channel structures 310 may be located in the second sub-region 012 of the array region 01. The plurality of second channel structures 320 may be located in the first sub-region 011 of the array region 01. The plurality of third channel structures may be located in the connection region 02.

The plurality of second channel structures and the plurality of third channel structures may support the semiconductor intermediate in the above-described process of removing the gate sacrificial layer to reduce cases in which the semiconductor intermediate deforms and collapses. As an option, it is possible to select the layout of the second channel structures and third channel structures in x-y plane and the numbers thereof according to different configurations of the semiconductor device architecture to reduce the overall occupied size of the second channel structures and the third channel structures in the completed semiconductor device while functioning to support, thereby increasing the storage density of the semiconductor device.

Optionally, the radial size of at least one of the second channel structure 320 and the third channel structure may be greater than or equal to the radial size of the first channel structure 310, where the radial size may be interpreted as the size of the structure in the plane intersecting z-direction (e.g., x-y plane).

Optionally, the second channel structure 320 and the third channel structure may have the same layer structure as the first channel structure 310. For example, the second channel structure 320 and the third channel structure may also include a functional layer 301 and a channel layer 302 on the surface of the functional layer 301.

As another option, considering that the second channel structure 320 and the third channel structure only function to support, the second channel structure 320 and the third channel structure may also have different layer structure from the first channel structure 310.

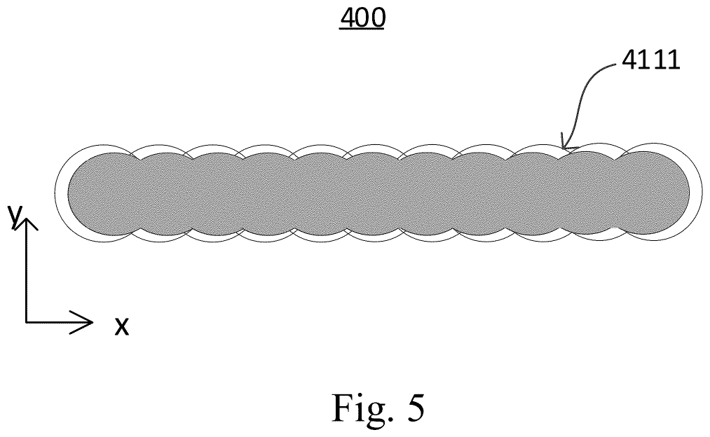

FIG. 5 is a top view of a gate line isolation structure 400, according to an implementation of the present disclosure.

Referring to FIGS. 1 and 5, in some implementations of the present disclosure, at least one surface 4111 of the gate line isolation structure 400 (which may be understood as a surface of a side wall of the gate line isolation structure 400, hereinafter side wall 4111) includes curved surface, which includes at least one of concave surface and convex surface. Furthermore, the gate line isolation structure 400 extends wavily in x-direction.

In particular, the gate line isolation structure 400 includes a side wall 4111 in contact with the stack structure 200, in which the side wall 4111 is a curved surface including at least one of concave surface and convex surface. Optionally, the side wall 4111 of the gate line isolation structure 400 has wavy shape on both sides in x-direction. Optionally, a side wall 4111 of the first section 410 includes a curved surface including at least one of concave surface and convex surface. Furthermore, the side wall 4111 of the first section 410 has wavy shape on both sides in x-direction. Optionally, a side wall 4111 of the second section 420 includes a curved surface including at least one of concave surface and convex surface. Furthermore, the side wall 4111 of the second section 420 has wavy shape on both sides in x-direction.

In other words, in the present implementation, the gate line isolation structure 400 may be formed by forming gate line slits such as first slit and second slit first in the stack structure (not shown) including the gate sacrificial layer and filling the gate line slits. As an option, the gate line slits containing the gate line isolation structure 400 may be formed by forming first holes (not shown) first and then removing at least a part of the stack structure between adjacent first holes. Therefore, the side wall of the gate line slits in contact with the stack structure is a curved surface, and the side wall 4111 of the gate line isolation structure 400 formed in gate line slits includes curved surface too.

In the present implementation, the gate line slits containing the gate line isolation structure 400 are formed in operations. The first holes that are formed first may be formed together with “deep holes” of other structures in the semiconductor device 1000, and then a plurality of first holes are communicated to form gate line slits by “hole expanding” process, such as first slit, second slit. By forming various holes of different structures for the semiconductor device 1000 such as first channel hole, second channel hole and first holes in the same process, it is possible to effectively reduce the number of etching processes used to form high aspect ratio structures, which in turn reduce the difficulty of fabricating the semiconductor device 1000 and the costs of fabricating the semiconductor device 1000.

Furthermore, various holes of different structures for the semiconductor device 1000 may be fabricated with the same mask since they are formed in the same process, which may improve overlay accuracy in the etching process, reduce the overlay error and allow the completed semiconductor device 1000 to have high overall performance.

Optionally, referring to FIG. 4, the gate line isolation structure 400, such as first section 410 or second section 420, may include a gate line isolation layer 112 and a gate line fill layer 111 on a surface of the gate line isolation layer 112. Optionally, the material for the gate line isolation layer 112 may include at least one of a high dielectric constant dielectric layer and an insulating dielectric material layer such as silicon oxide layer. Furthermore, the material for the gate line filling layer 111 may include at least one of semiconductor material such as poly-crystalline silicon and insulating dielectric material layer such as silicon oxide, silicon nitride and silicon oxynitride. Optionally, the material for the gate line filling layer 111 may further include conductive material layer. The internal filler material for the gate line isolation structure 400 is not limited in the present disclosure.

Referring again to FIGS. 1, 3 and 4, the second spacer structure 432 includes a plurality of isolation layers 4321, where the isolation layers 4321 may be stacked alternatively with first dielectric layers 210 in z-direction and disposed in the same layer as gate layers 220. Optionally, the material for the isolation layer 4321 may include any suitable insulating dielectric material. For example, the isolation layer 4321 includes insulating dielectric material layer such as silicon oxide layer. As an option, the isolation layer 4321 may include the same insulating dielectric material layer as the first dielectric layer 210. In this case, there are still boundaries between the isolation layers 4321 and the first dielectric layers 210 since the forming processes for the isolation layers 4321 and the first dielectric layers 210 are different.

Furthermore, the second spacer structure 432 further includes an isolation post 4322 extending in z-direction and including the same insulating dielectric material as the isolation layers 4321.

Referring to FIGS. 1 and 3, the first spacer structure 431 is surrounded by the second spacer structure 432 and extends through a plurality of isolation layers 4321 in z-direction.

Optionally, the first spacer structure 431 and the second spacer structure 432 are both located in the first sub-region 011 of the array region 01 close to the connection region 02. In the present implementation, the first section 410 extends in x-direction and is located in the second sub-region 012 of the array region 01 away from the connection region 02; and the second section 420 extends in x-direction into the connection region 02 from the first sub-region 011 of the array region 01.

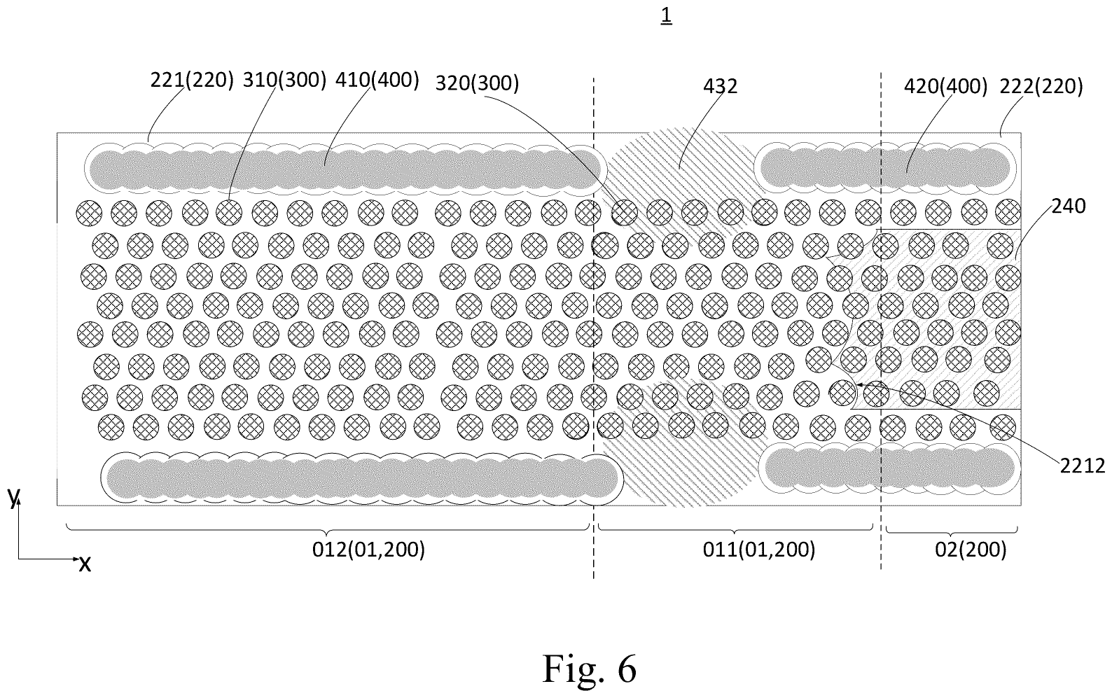

FIG. 6 is a top view of a semiconductor device 1, according to an implementation of the present disclosure.

As shown in FIG. 6, in the present implementation, a semiconductor device 1 includes a stack structure 200, a gate line isolation structure 400 and a second spacer structure 432. The second spacer structure 432 divides the gate line isolation structure 400 into a first section 410 and a second section 420 disposed with an interval in x-direction. Similarly, in the process of fabricating the semiconductor device 1, the second spacer structure 432 may divide the first slit and the second slit and the gate sacrificial layer may be removed by means of the first slit and the second slit. However, in the process, since other parts of the semiconductor intermediate all have “deep holes” (not shown) formed by etching process such as the first channel hole, the second channel hole etc., while there is no “deep hole” in the region in which the second spacer structure 432 resides since the first slit and second slit need to be divided. This could cause non-uniform stress at various locations in the semiconductor intermediate. “Deep holes” adjacent to the region in which the second spacer structure 432 resides will experience topology shift due to the above-described non-uniform stress, which in turn results in poor uniformity and consistency of the plurality of channel structures in the completed semiconductor device.

With respect to FIGS. 1 and 6, the second spacer structure 432 surrounds the first spacer structure 431, or in other words, at least one first spacer structure 431 is disposed in the second spacer structure 432. By means of the “deep holes” formed while forming the first spacer structure 431, it is possible to improve the stress in the region in which the second spacer structure resides, reduce topology shifts of the plurality of channel structures corresponding to the region, which in turn improves the uniformity and consistency of the plurality of channel structures and improves stability and conductivity of the semiconductor device.

Optionally, referring to FIG. 1, in order to optimize the above effects, in some implementations of the present disclosure, the first spacer structure 431 may include a first separating structure 4311 and a second separating structure 4312, where the first separating structure 4311 is closer to the first section 410 in x-direction than the second separating structure 4312, and the second separating structure 4312 is closer to the second section 420 in x-direction than the first separating structure 4311. In other words, the first section 410, the first separating structure 4311, the second separating structure 4312 and the second section 420 may be arranged in x-direction sequentially. By improving the position relationship between the first separating structure or the second separating structure and the gate line isolation structure, it is possible to improve the partial stress distribution in the region in which the second spacer structure resides in the semiconductor intermediate.

Optionally, as shown in FIG. 2, in order to optimize the above effects and improve the stress in particular direction in the region in which the second spacer structure resides in the semiconductor intermediate, the size c2 of the first spacer structure 431 in x-direction may be greater than the size c1 of the first spacer structure in the third direction (y-direction), where y-direction intersects both the x and z-direction. In other words, in the process of fabricating the semiconductor device, the “deep hole” that contains the first spacer structure 431 may be a “trench” having a high aspect ratio structure, where the “deep hole” may be understood as a 2D pattern with a circular cross section in a direction perpendicular to its extension direction, and the “trench” may be understood as an asymmetrical 2D pattern with an oval or rectangular cross section in a direction perpendicular to its own extension direction.

Optionally, as shown in FIGS. 1 and 3, in order to optimize the above effects, it is possible to increase the number of “deep holes” generated while forming the first spacer structure 431 and the first spacer structure 431 may include a plurality of post structures arranged with intervals in x-direction. For example, the first separating structure 4311 may include a plurality of post structures arranged with intervals in x-direction and the second separating structure 4312 may include a plurality of post structures arranged with intervals in x-direction.

Furthermore, in order to optimize the above effects, it is possible to increase the radial size of “deep holes” generated while forming the first spacer structure 431 and the sizes in y-direction of the first section 410 or the second section 420 may be less than or equal to the size of the first spacer structure 431 in y-direction.

Optionally, the extension size D of the second spacer structure 432 in the direction intersecting z-direction (e.g., x-direction or y-direction) may satisfy: 400 nm≤D≤1500 nm. By reasonably controlling the extension length of the second spacer structure, it is possible to increase the length of effective storage region including the plurality of first channel structures 310 in the semiconductor device and improve the storage capacity of the semiconductor device.

Therefore, the semiconductor device according to at least one implementation of the present disclosure includes a stack structure, a gate line isolation structure, a first spacer structure and a second spacer structure, where the first spacer structure and the second spacer structure divide the gate line isolation structure into a first section and a second section arranged with an interval in the extension direction of the gate line isolation structure. The gate layer of the stack structure may be fabricated with gate last process. For example, a gate sacrificial layer is formed in advance. In the process of etching off the gate sacrificial layer with e.g., wet etching, the etchant and chemical precursor are brought into contact with gate sacrificial layer and in turn remove partial gate sacrificial layer to form the gate layer by means of gate line slits formed while forming the gate line isolation structure, such as the first gate line slit and the second gate line slit. The first spacer structure and the second spacer structure divide the gate line isolation structure into the first section and the second section; and similarly the first spacer structure and the second spacer structure separate the first slit and the second slit in the process of fabricating the semiconductor device, which can reduce the case in which excess etch solution flows into other structures that have been formed in the semiconductor intermediate via gate line slits in the process of removing gate sacrificial layer with gate last process in fabricating the semiconductor device, thereby improving comprehensive performance of the semiconductor device.

Moreover, the semiconductor device further includes a channel structure. The second spacer structure surrounds the first spacer structure, which may improve the stress of the part of the stack structure at which the first spacer structure and the second spacer structure are located, reduce the cases in which topology of multiple channel structures corresponding to them shift, thereby improving the uniformity and consistency of the multiple channel structures and improving the comprehensive performance of semiconductor device.

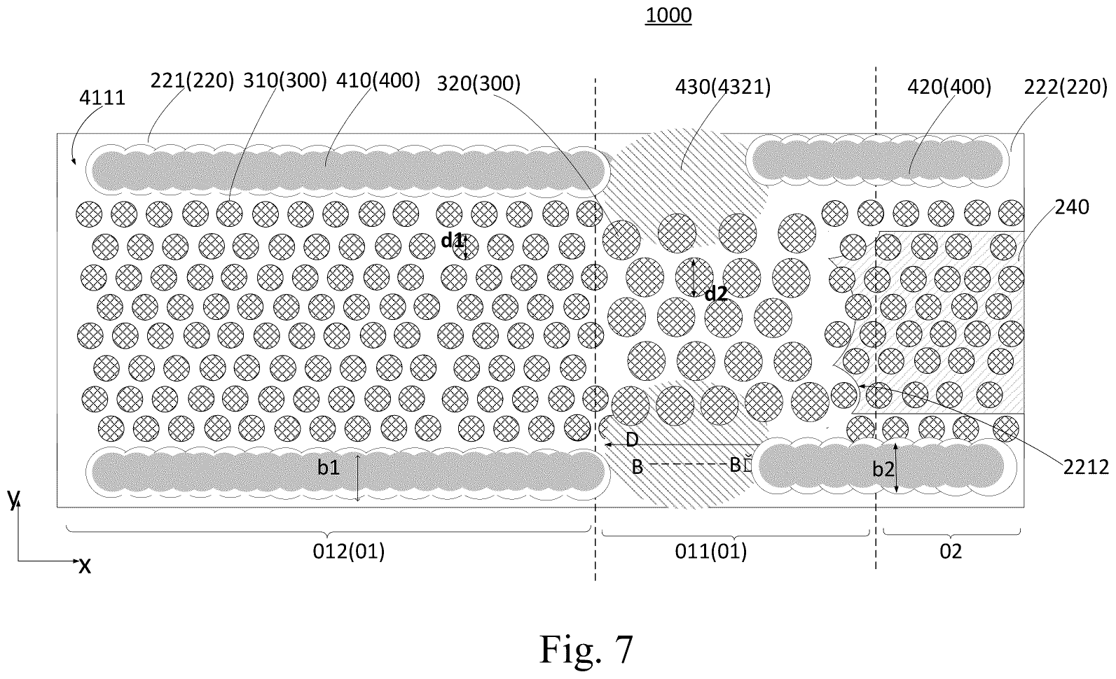

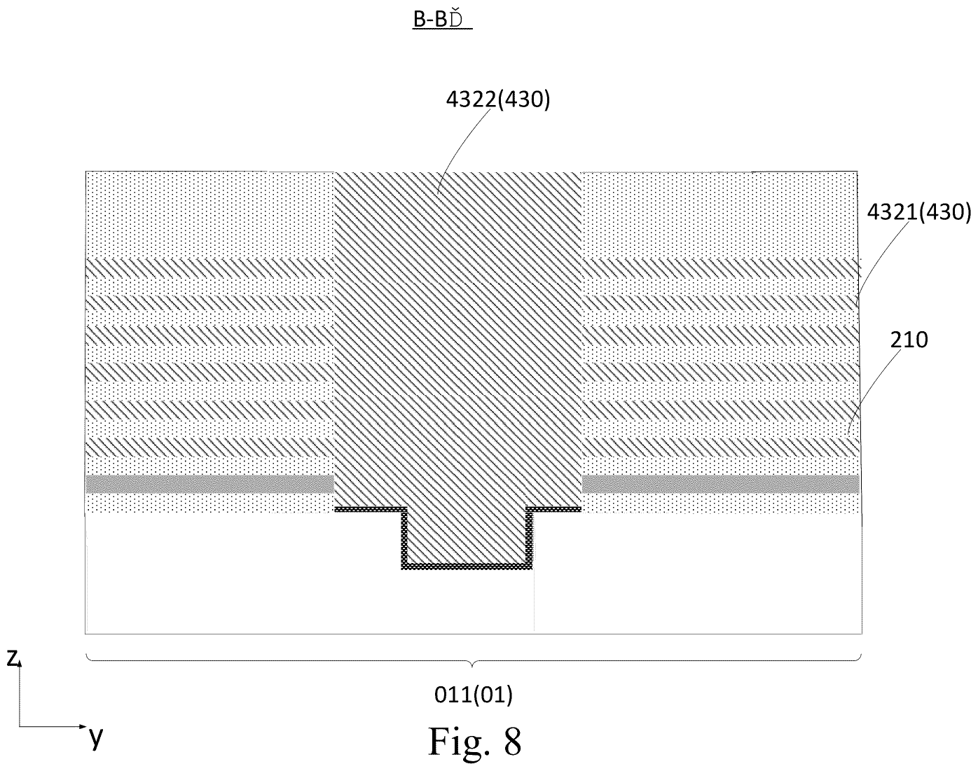

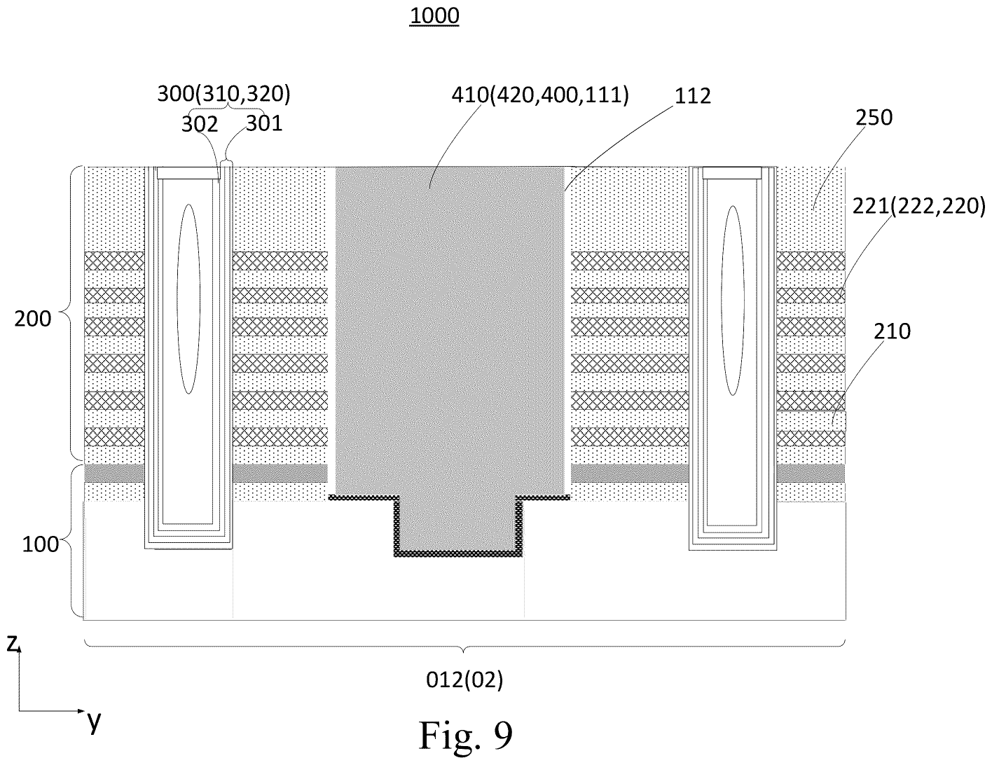

FIG. 7 is a top view of a semiconductor device 1000 according to another implementation of the present disclosure. FIG. 8 is a cross-sectional diagram of the semiconductor device 1000 shown in FIG. 7 taken along line B-B′. FIG. 9 is a cross-sectional diagram of a semiconductor device 1000 according to yet another implementation of the present disclosure.

As shown in FIGS. 7-9, another aspect of the present disclosure provides a semiconductor device 1000 that may include a stack structure 200, a gate line isolation structure 400, a first channel structure 310, a second channel structure 320 and a spacer structure 430. The stack structure 200 includes first dielectric layers 210 and gate layers 220 stacked alternatively in the first direction (e.g., z-direction). The gate line isolation structure 400 extends in the stack structure 200 along the second direction (e.g., x-direction) intersecting the z-direction and includes a first section 410 and a second section 420 arranged with an interval in x-direction. The spacer structure 430 is located between the first section 410 and the second section 420. Both the first channel structure 310 and the second channel structure 320 extend in z-direction in the stack structure 200, where a plurality of second channel structures 320 are located on a side of the spacer structure 430 in the third direction (y-direction), y-direction intersect both the x-direction and z-direction, and the size d2 of the second channel structure 320 is greater than the size d1 of the first channel structure 310 in the direction intersecting z-direction (e.g., x-direction or y-direction).

It is to be noted that in order to facilitate observing shapes and locations of structures other than the gate layer 220 in the semiconductor device 1000, only the profile of the gate layer 220 is illustrated with black lines in FIG. 7.

The gate layer of the stack structure provided in implementations of the present disclosure may be fabricated with gate last process. For example, a gate sacrificial layer is formed in advance. In the process of etching off the gate sacrificial layer with e.g., wet etching, the etchant and chemical precursor are brought into contact with gate sacrificial layer and in turn remove partial gate sacrificial layer to form the gate layer by means of gate line slits formed while forming the gate line isolation structure, such as the first gate line slit and the second gate line slit. The spacer structure divides the gate line isolation structure into the first section and the second section; and similarly the spacer structure separates the first slit and the second slit in the process of fabricating the semiconductor device, which can reduce the case in which excess etch solution flows into other structures that have been formed in the semiconductor intermediate via gate line slits in the process of removing gate sacrificial layer with gate last process in fabricating the semiconductor device, thereby improving comprehensive performance of the semiconductor device.

Moreover, the spacer structure and the plurality of second channel structures are arranged along a direction intersecting both the stacking direction of the stack structure and the extension direction of the gate line isolation structure, and in the direction intersecting the stacking direction, the size of the second channel structure is configured to be greater than the size of the first channel structure, which may improve stress of the part of the stack structure at which the spacer structure is located, reduce the cases in which topology of the second channel structures shift, thereby improving the uniformity and consistency of the multiple channel structures and improving the comprehensive performance of semiconductor device.

In particular, as shown in FIG. 9, the stack structure 200 may be disposed on a side of the substrate 100. The material for the substrate 100 may include semiconductor materials which may include, but not limited to elementary semiconductor material such as silicon, germanium, III-V compound semiconductor material, II-VI compound semiconductor material, organic semiconductors material or other semiconductor material known in the art. Illustratively, the substrate 100 may include a silicon substrate. In addition, the substrate 100 may be a composite structure. For example, the composite structure may include a layer structure connected with the channel structure 300, where the channel structure 300 will be described in detail below with reference to drawings.

As shown in FIGS. 7 and 9, the stack structure 200 may include an array region 01 and connection region 02 arranged adjacently in x-direction, where the array region 01 may include a first sub-region 011 and a second sub-region 012 adjacent in x-direction, and the first sub-region 011 is closer to the connection region 02 than the second sub-region 012.

As an option, the gate layer 220 may include a conductive material, for example, any one or combination of tungsten (W), cobalt (Co), copper (Cu), aluminum (Al), doped crystalline silicon or silicide. The first dielectric layer 210 may function as an isolation stack, including, but not limited to insulating dielectric material layers such as silicon oxide layer.

In addition, the stack structure 200 further includes a plurality of second dielectric layers 240. The second dielectric layer 240 and the first dielectric layer 210 are two different insulating dielectric layers. For example, the second dielectric layer 240 may include, but not limited to insulating dielectric layer such as silicon nitride layer. Furthermore, the plurality of second dielectric layers 240 and the plurality of gate layers 220 may have the same stacking height. Optionally, the number of layers of the stack structure 200 is not limited to that shown in the figure, and can be otherwise configured as required, for example, 32, 64, 128 etc.

In other words, the stack structure 200 may include first dielectric layers 210 and composite layers stacked alternatively, where the composite layer may include the gate layer 220 and second dielectric layer 240 disposed in the same layer. For example, the gate layers 220 and the second dielectric layers 240 may be connected with each other in the x-y plane intersecting z-direction. The gate layers 220 extend to the connection region 02 from the array region 01 of the stack structure 200 in x-direction and is connected with the second dielectric layer 240 disposed in the same layer, where the second dielectric layers 240 are located in the connection region 02.

Optionally, as shown in FIG. 7, the gate layer 220 may include a first portion 221 in the array region 01 and a second portion 222 in the connection region 02 which are connected with each other. Furthermore, the surface 2212 of the first portion 221 facing the connection region 02 includes a curved surface including at least one of concave surface and convex surface. This can release the local stress of the semiconductor device and improve the stability of semiconductor device.

Furthermore, as shown in FIG. 9, the stack structure 200 may further include a dielectric covering layer 250 that may be fabricated with the same material as the first dielectric layer 210. Optionally, a size of the dielectric covering layer 250 in z-direction may be greater than a size of the first dielectric layer 210 or the gate layer 220 in z-direction.

In addition, as shown in FIGS. 7 and 9, in some implementations of the present disclosure, the semiconductor device 1000 further includes a channel structure 300 extending in z-direction in the stack structure 200, where the channel structure 300 may include a first channel structure 310 and a second channel structure 320, and in the direction intersecting z-direction (e.g., x-direction or y-direction), the size d2 of the second channel structure 320 is greater than the size d1 of the first channel structure 310.

For example, in the direction intersecting z-direction (e.g., x-direction or y-direction), the size d1 of the first channel structure 310 and the size d2 of the second channel structure 320 may satisfy: 1.1d1≤d2.

As an option, in the direction intersecting z-direction (e.g., x-direction or y-direction), the size d2 of the second channel structure 320 may satisfy: 110 nm<d2≤150 nm.

Optionally, the first channel structure 310 may be located in the second sub-region 012 of the array region 01, and the second channel structure 320 may be located in the first sub-region 011 of the array region 01 and arranged along with the spacer structure 430 in y-direction.

For example, a part of the plurality of second channel structure 320 may be located on a side of the spacer structure 430 in y-direction, and the other part of the plurality of second channel structures 320 may be located in the spacer structure 430.

Furthermore, the channel structure 300 may include a third channel structure that may be located in the second sub-region. The plurality of second channel structures and plurality of third channel structures may support the semiconductor intermediate in the above-described process of removing gate sacrificial layer to reduce cases in which the semiconductor intermediate deforms and collapses. As an option, it is possible to select the layout of the second channel structures and third channel structures in x-y plane and the numbers thereof according to different configurations of the semiconductor device architecture to reduce the overall occupied size of the second channel structures and the third channel structures in the completed semiconductor device while functioning to support, thereby increasing the storage density of the semiconductor device.

Optionally, in the direction intersecting z-direction (e.g., x-direction or y-direction), the size of the third channel structure may be greater than or equal to the size d1 of the first channel structure 310. Optionally, in the direction intersecting z-direction (e.g., x-direction or y-direction), the size of the third channel structure may be greater than or equal to the size d2 of the second channel structure 320.

The first channel structure 310 includes a functional layer 301 and a channel layer 302 on the surface of the functional layer 301. The functional layer 301 may include a blocking layer, a charge trapping layer and a tunneling layer disposed in turn on inner wall of the channel hole (not shown). In some implementations, the functional layer 301 may include an oxide-nitride-oxide (ONO) structure. However, in some other implementations, the functional layer 301 may have a structure different from ONO configuration. The channel layer 302 may be on the surface of the tunneling layer and can carry required charges (electrons or holes). The channel layer 302 may be fabricated from semiconductor material such as poly-crystalline silicon or single crystalline silicon and may have conductive impurities. Furthermore, the channel structure 300 may further include a channel filling dielectric layer filled in the remained space in the channel hole after forming the functional layer 301 and the channel layer 302. The channel filling dielectric layer includes insulating dielectric material layers such as silicon oxide layer.

The second channel structure 320 and the third channel structure may function to support in the above-described process of removing gate sacrificial layer to reduce cases in which the semiconductor intermediate deforms and collapses. Therefore, it is possible to select the layout of the second channel structures and third channel structures in x-y plane and the numbers thereof according to different configurations of the semiconductor device architecture to reduce the overall occupied size of the second channel structures and the third channel structures in the completed semiconductor device while functioning to support, thereby increasing the storage density of the semiconductor device.

As an option, the second channel structure 320 and the third channel structure may have the same layer structure as the first channel structure 310. For example, the second channel structure 320 and the third channel structure may also include a functional layer 301 and a channel layer 302 on the surface of the functional layer 301.

As another option, considering that the second channel structure 320 and the third channel structure only function to support, the second channel structure 320 and the third channel structure may also have different layer structure from the first channel structure 310.

As shown in FIG. 9, the gate line isolation structure 400 such as first section 410 or second section 420 may include a gate line isolation layer 112 and a gate line fill layer 111 on a surface of the gate line isolation layer 112. Optionally, the material for the gate line isolation layer 112 may include at least one of a high dielectric constant dielectric layer and an insulating dielectric material layer such as silicon oxide layer. Furthermore, the material for the gate line filling layer 111 may include at least one of semiconductor material such as poly-crystalline silicon and insulating dielectric material layer such as silicon oxide, silicon nitride and silicon oxynitride. Optionally, the material for the gate line filling layer 111 may further include conductive material layer. The internal filler material for the gate line isolation structure 400 is not limited in the present disclosure. In other words, at least one of the first section 410 and the second section 420 may include a gate line isolation layer 112 and a gate line fill layer 111 on a surface of the gate line isolation layer 112.

Furthermore, referring to FIG. 7, in some implementations of the present disclosure, at least one surface 4111 of the gate line isolation structure 400 (which may be understood as a surface of a side wall of the gate line isolation structure 400, hereinafter side wall 4111) includes curved surface which includes at least one of concave surface and convex surface. Furthermore, the gate line isolation structure 400 extends wavily in x-direction.

In particular, the gate line isolation structure 400 includes a side wall 4111 in contact with the stack structure 200 (as shown in FIG. 9), in which the side wall 4111 is a curved surface including at least one of concave surface and convex surface. For example, a side wall 4111 of the first section 410 is a curved surface including at least one of concave surface and convex surface, and a side wall 4111 of the second section 420 is a curved surface including at least one of concave surface and convex surface.

Optionally, the side wall 411 of the gate line isolation structure 400 has wavy shape on both sides in x-direction. For example, the side wall 4111 of the first section 410 has wavy shape on both sides in x-direction, and the side wall 4111 of the second section 420 has wavy shape on both sides in x-direction.

In other words, in the present implementation, the gate line isolation structure 400 may be formed by forming gate line slits such as first slit and second slit first in the stack structure (not shown) including gate sacrificial layer and filling the gate line slits. As an option, the gate line slits containing the gate line isolation structure 400 may be formed by forming first holes (not shown) first and then removing at least a part of the stack structure between adjacent first holes. Therefore, the side wall of the gate line slits in contact with the stack structure is a curved surface, and the side wall 4111 of the gate line isolation structure 400 formed in gate line slits includes curved surface too.

structure 400 are formed in operations. The first holes that are formed first may be formed together with “deep holes” of other structures in the semiconductor device 1000, and then a plurality of first holes are communicated to form gate line slits by “hole expanding” process, such as first slit, second slit. By forming various holes of different structures in the semiconductor device 1000 such as first channel hole, second channel hole and first holes in the same process, it is possible to effectively reduce the number of etching processes used to form high aspect ratio structures, which in turn reduce the difficulty of fabricating the semiconductor device 1000 and the costs of fabricating the semiconductor device 1000.

Furthermore, various holes of different structures in the semiconductor device 1000 may be fabricated with the same mask since they are formed in the same process, which may improve overlay accuracy in the etching process, reduce the overlay error and allow the completed semiconductor device 1000 to have high overall performance.

Optionally, the first section 410 of the gate line isolation structure 400 extends in x-direction and is located in the second sub-region 012 of the array region 01 away from the connection region 02; and the second section 420 extends in x-direction into the connection region 02 from the first sub-region 011 of the array region 01.

As an option, the size b1 of the first section 410 in y-direction is less than or equal to the size b2 of the second section 420 in y-direction. For example, the size b1 of the first section 410 in y-direction and the size b2 of the second section 420 in y-direction may satisfy: 1.1b1≤b2. Furthermore, the size b2 of the second section 420 in y-direction may satisfy: 300 nm<b2≤900 nm.

As noted above, the first slit for containing the first section 410 and the second slit for containing the second section 420 may be formed by forming the first holes first and then “expanding” the holes. Therefore, the plurality of first holes for forming the first slit and the plurality of first holes for forming the second slit may have the same size in x-y plane, thereby simplifying the difficulty of the etching process for forming the high aspect ratio structures. Then the partial size of the first slit or second slit in x-y plane is changed with “hole expanding” process to satisfy demands of different semiconductor devices, where the x-y plane may be understood as the plane intersecting z-direction.

As shown in FIG. 6, the semiconductor device 1 includes a stack structure 200, a gate line isolation structure 400 and a second spacer structure 432. The second spacer structure 432 divides the gate line isolation structure 400 into a first section 410 and a second section 420 disposed with an interval in x-direction. In the present implementation, since in the process of fabricating the semiconductor device 1, there is no “deep hole” with high aspect ratio in the region in which the second spacer structure 432 resides due to the first slit and second slit generated while diving it into the first section 410 and the second section 420. However, there are many “deep holes” in other regions of the semiconductor intermediate. This could cause non-uniform stress at various locations in the semiconductor intermediate. “Deep holes” adjacent to the region in which the second spacer structure 432 resides will experience topology shift due to the above-described non-uniform stress, which in turn results in poor uniformity and consistency of the plurality of channel structures in the completed semiconductor device.

In at least one implementation of the present disclosure, the semiconductor device 1000 may include a stack structure 200, a gate line isolation structure 400, a first channel structure 310, a second channel structure 320 and a spacer structure 430. The spacer structure 430 is located between the first section 410 and the second section 420 of the gate line isolation structure 400. The plurality of second channel structures 320 and the spacer structure 430 are arranged in y-direction. In the direction intersecting z-direction (e.g., x-direction or y-direction), the size d2 of the second channel structure 320 may be greater than the size d1 of the first channel structure 310. Therefore, in the process of fabricating the semiconductor device 1000, a part of the second channel hole for containing the second channel structure 320 may be adjacent to the region in which the spacer structure 430 resides, and the other part may be locate in the spacer structure 430, and the size of the second channel structure in the direction intersecting its own extension direction is greater than the size of “deep holes” in other regions of the semiconductor intermediate in the direction intersecting their own extension direction. It is possible to improve the stress in the region in which the spacer structure resides, reduce topology shifts of the plurality of channel structures corresponding to the region, which in turn improves the uniformity and consistency of the plurality of channel structures and improves stability and conductivity of the semiconductor device.

Optionally, the extension size D of the spacer structure 430 in the direction intersecting z-direction (e.g., x-direction or y-direction) may satisfy: 400 nm≤D≤1500 nm. By reasonably controlling the extension length of the spacer structure, it is possible to increase the length of effective storage region including the plurality of first channel structures 310 in the semiconductor device and improve the storage capacity of the semiconductor device.

Optionally, as shown in FIGS. 7-9, the spacer structure 430 includes a plurality of isolation layers 4321, where the isolation layers 4321 may be stacked alternatively with first dielectric layers 210 in z-direction and disposed in the same layer as gate layers 220. Optionally, the material for the isolation layer 4321 may include any suitable insulating dielectric material. For example, the isolation layer 4321 includes insulating dielectric material layers such as silicon oxide layer. As an option, the isolation layer 4321 may include the same insulating dielectric material layer as the first dielectric layer 210. In this case, there are still boundaries between the isolation layers 4321 and the first dielectric layers 210 since the forming processes for the isolation layer 4321 and the first dielectric layer 210 are different.

Furthermore, the spacer structure 430 further includes an isolation post 4322 extending in z-direction and including the same insulating dielectric material as the isolation layers 4321. Optionally, the isolation post 4322 is on a side of the second channel structure 320 in y-direction.

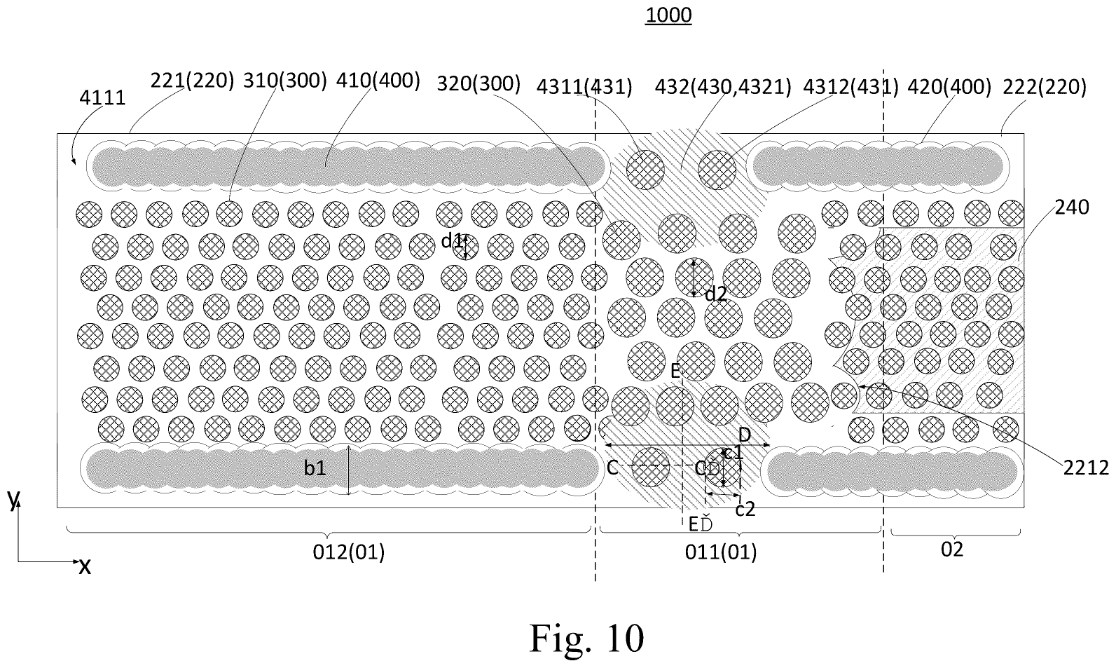

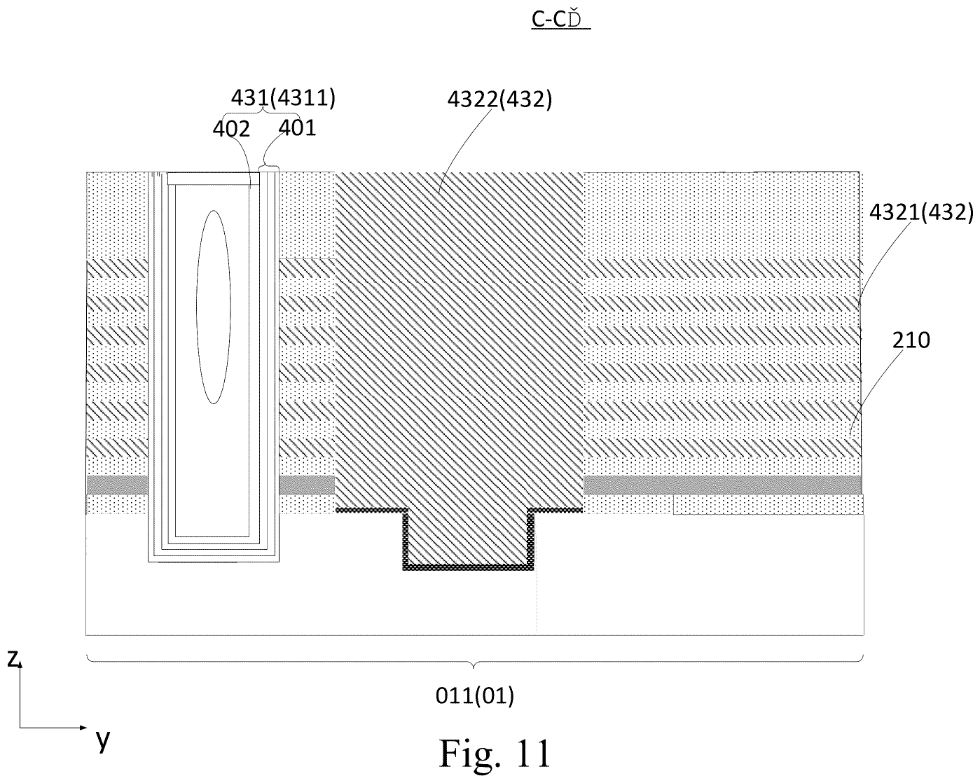

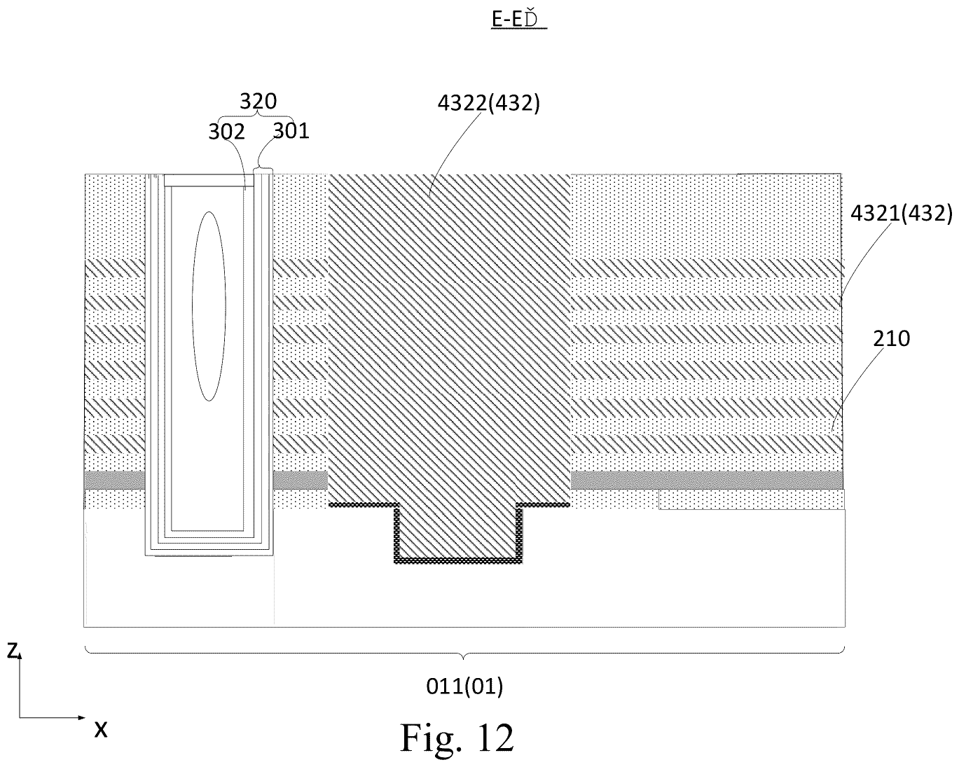

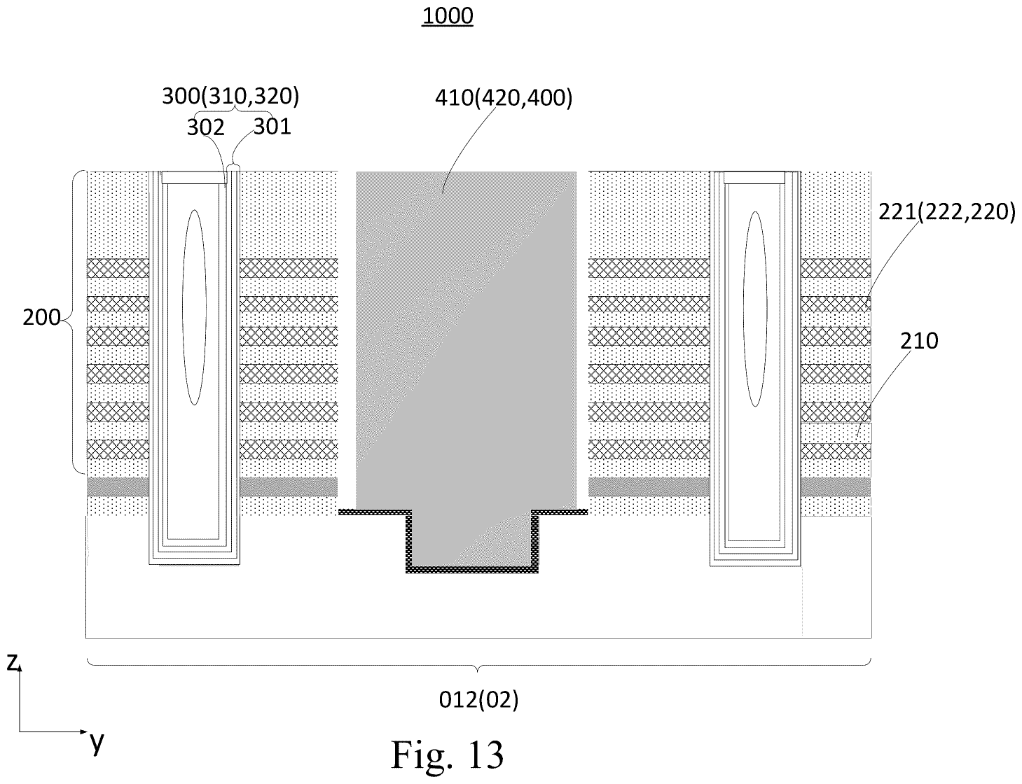

FIG. 10 is a top view of a semiconductor device 1000 according to another implementation of the present disclosure. FIG. 11 is a cross-sectional diagram of the semiconductor device 1000 shown in FIG. 10 taken along line C-C′. FIG. 12 is a cross-sectional diagram of the semiconductor device 1000 shown in FIG. 10 taken along line E-E′. FIG. 13 is a cross-sectional diagram of a semiconductor device 1000 according to yet another implementation of the present disclosure.

As shown in FIGS. 10-13, another aspect of the present disclosure provides a semiconductor device 1000 that may include a stack structure 200, a gate line isolation structure 400, a first channel structure 310, a second channel structure 320 and a spacer structure 430, where the spacer structure 430 includes a first spacer structure 431 and a second spacer structure 432 surrounding the first spacer structure 431. The stack structure 200 includes first dielectric layers 210 and gate layers 220 stacked alternatively in the first direction (e.g., z-direction). The gate line isolation structure 400 extends in the stack structure 200 along the second direction (e.g., x-direction) intersecting the z-direction and includes a first section 410 and a second section 420 arranged with an interval in x-direction. The spacer structure 430 is located between the first section 410 and the second section 420. Both the first channel structure 310 and the second channel structure 320 extend in z-direction in the stack structure 200, where a plurality of second channel structures 320 and the spacer structure 430 are arranged in the third direction (y-direction), y-direction intersect both the x-direction and z-direction, and the size d2 of the second channel structure 320 is greater than the size d1 of the first channel structure 310 in the direction intersecting z-direction (e.g., x-direction or y-direction), and in addition, the second spacer structure 432 may surround the first spacer structure 431.

It is to be noted that in order to facilitate observing shapes and locations of structures other than the gate layer 220 in the semiconductor device 1000, only the profile of the gate layer 220 is illustrated with black lines in FIG. 10.

The gate layer of the stack structure provided in implementations of the present disclosure may be fabricated with gate last process. For example, a gate sacrificial layer is formed in advance. In the process of etching off the gate sacrificial layer with e.g., wet etching, the etchant and chemical precursor are brought into contact with gate sacrificial layer and in turn remove partial gate sacrificial layer to form the gate layer by means of gate line slits formed while forming the gate line isolation structure, such as the first gate line slit and the second gate line slit. The first spacer structure and the second spacer structure divide the gate line isolation structure into the first section and the second section; and similarly the first spacer structure and the second spacer structure separate the first slit and the second slit in the process of fabricating the semiconductor device, which can reduce the case in which excess etch solution flows into other structures that have been formed in the semiconductor intermediate via gate line slits in the process of removing gate sacrificial layer with gate last process while fabricating the semiconductor device, thereby improving comprehensive performance of the semiconductor device.

Moreover, the second spacer structure of the spacer structure surrounds the first spacer structure, and the plurality of second channel structures and the spacer structures are arranged along the third direction, and in the direction intersecting the stacking direction of the stack structure, the size of the second channel structure is greater than the size of the first channel structure, which may improve stress of the part of the stack structure at which the spacer structure is located, reduce the cases in which topology of the plurality of channel structures corresponding to the spacer structures shift, thereby improving the uniformity and consistency of the multiple channel structures and improving the comprehensive performance of semiconductor device.

In particular, as shown in FIG. 10, in some implementations of the present disclosure, the first spacer structure 431 may include a first separating structure 4311 and a second separating structure 4312, where the first separating structure 4311 is closer to the first section 410 in x-direction than the second separating structure 4312, and the second separating structure 4312 is closer to the second section 420 in x-direction than the first separating structure 4311. In other words, the first section 410, the first separating structure 4311, the second separating structure 4312 and the second section 420 are arranged in x-direction sequentially. By improving the position relationship between the first separating structure or the second separating structure and the gate line isolation structure, it is possible to improve the partial stress distribution in the region in which the second spacer structure resides in the semiconductor intermediate.

Furthermore, in some implementations of the present disclosure, in order to optimize the above-described effects, it is possible to increase the number of “deep holes” generated while forming the first spacer structure 431. In other words, the first spacer structure 431 may include a plurality of post structures arranged with intervals in x-direction. In particular, the first separating structure 4311 may include a plurality of post structures arranged with intervals in x-direction and the second separating structure 4312 may include a plurality of post structures arranged with intervals in x-direction.

As shown in FIGS. 11 and 12, in some implementations of the present disclosure, the first spacer structure 431 may have the same layer structure as the channel structure 300. In other words, considering the second channel structure 320 as an example, the channel structure 300 may include a functional layer 301 and a channel layer 302 on the surface of the functional layer 301. The first spacer structure 431 may include a first layer 401 and a second layer 402 on the surface of the first layer 401. The first layer 401 may have the same layer structure as the functional layer 301 and may include an oxide-nitride-oxide (ONO) structure. However, in some other implementations, the first layer 401 may also have a structure different from ONO configuration. The second layer 402 and the channel layer 302 have the same layer structure. The second layer 402 may be fabricated from semiconductor material such as poly-crystalline silicon or single crystalline silicon and may have conductive impurities. Furthermore, the first spacer structure 431 may also include a third layer having the same layer structure as the channel filling dielectric layer of the channel structure. The third layer may include insulating dielectric material layers such as silicon oxide layer.

Furthermore, the first spacer structure 431 may also be formed in the same process as the channel structure 300 to simplify the fabrication process of semiconductor device and reduce the fabrication costs of semiconductor device.

As shown in FIG. 10, in some implementations of the present disclosure, in order to optimize the above effects and improve the stress in particular direction in the region in which the second spacer structure resides, the size c2 of the first spacer structure 431 in x-direction may be greater than the size c1 of the first spacer structure in y-direction. In other words, in the process of fabricating the semiconductor device, the “deep hole” that contains the first spacer structure 431 may be a “trench” having a high aspect ratio structure, where the “deep hole” may be understood as a 2D pattern with a circular cross section in a direction perpendicular to its extension direction, and the “trench” may be understood as an asymmetrical 2D pattern with an oval or rectangular cross section in a direction perpendicular to its own extension direction.

Furthermore, referring to FIGS. 10 and 13, in some implementations of the present disclosure, at least one surface 4111 of the gate line isolation structure 400 (which may be understood as a surface of a side wall of the gate line isolation structure 400, hereinafter side wall 4111) includes curved surface which includes at least one of concave surface and convex surface. Furthermore, the gate line isolation structure 400 extends wavily in x-direction.

The gate line isolation structure 400 includes a side wall 4111 in contact with the stack structure 200, in which the side wall 4111 is a curved surface including at least one of concave surface and convex surface. Optionally, the side wall 4111 of the gate line isolation structure 400 has wavy shape on both sides in x-direction. Optionally, a side wall 4111 of the first section 410 includes a curved surface including at least one of concave surface and convex surface. Furthermore, the side wall 4111 of the first section 410 has wavy shape on both sides in x-direction. Optionally, a side wall 4111 of the second section 420 includes a curved surface including at least one of concave surface and convex surface. Furthermore, the side wall 4111 of the second section 420 has wavy shape on both sides in x-direction.

In other words, in the present implementation, the gate line isolation structure 400 may be formed by forming gate line slits such as first slit and second slit first in the stack structure including gate sacrificial layer and filling the gate line slits. As an option, the gate line slits containing the gate line isolation structure 400 may be formed by forming first holes first and then removing at least a part of the stack structure between adjacent first holes. Therefore, the side wall of the gate line slits in contact with the stack structure is a curved surface, and the side wall 4111 of the gate line isolation structure 400 formed in gate line slits includes curved surface too.

In the present implementation, the gate line slits containing the gate line isolation structure 400 are formed in operations. The first holes that are formed first may be formed together with “deep holes” of other structures in the semiconductor device 1000, and then a plurality of first holes are communicated to form gate line slits by “hole expanding” process, such as first slit, second slit. By forming various holes of different structures in the semiconductor device 1000 such as first channel hole, second channel hole and first holes in the same process, it is possible to effectively reduce the number of etching processes used to form high aspect ratio structures, which in turn reduce the difficulty of fabricating the semiconductor device 1000 and the costs of fabricating the semiconductor device 1000.

Furthermore, various holes of different structures in the semiconductor device 1000 may be fabricated with the same mask since they are formed in the same process, which may improve overlay accuracy in the etching process, reduce the overlay error and allow the completed semiconductor device 1000 to have high overall performance. Therefore, the semiconductor device according to at least one implementation of the present disclosure includes a stack structure, a gate line isolation structure, a channel structure and a spacer structure, where the channel structure includes a first channel structure and a second channel structure, the spacer structure divides the gate line isolation structure into a first section and a second section arranged with an interval in the extension direction of the gate line isolation structure. This can reduce the case in which excess etch solution flows into other structures that have been formed in the semiconductor intermediate via gate line slits in the process of removing gate sacrificial layer with gate last process in fabricating the semiconductor device, thereby improving comprehensive performance of the semiconductor device.

Moreover, the spacer structure and the plurality of second channel structures are arranged along a direction intersecting both the stacking direction of the stack structure and the extension direction of the gate line isolation structure, and in the direction intersecting the stacking direction, the size of the second channel structure is configured to be greater than the size of the first channel structure, which may improve stress of the part of the stack structure at which the spacer structure is located, reduce the cases in which topology of the channel structures shift, thereby improving the uniformity and consistency of the multiple channel structures and improving the comprehensive performance of semiconductor device.

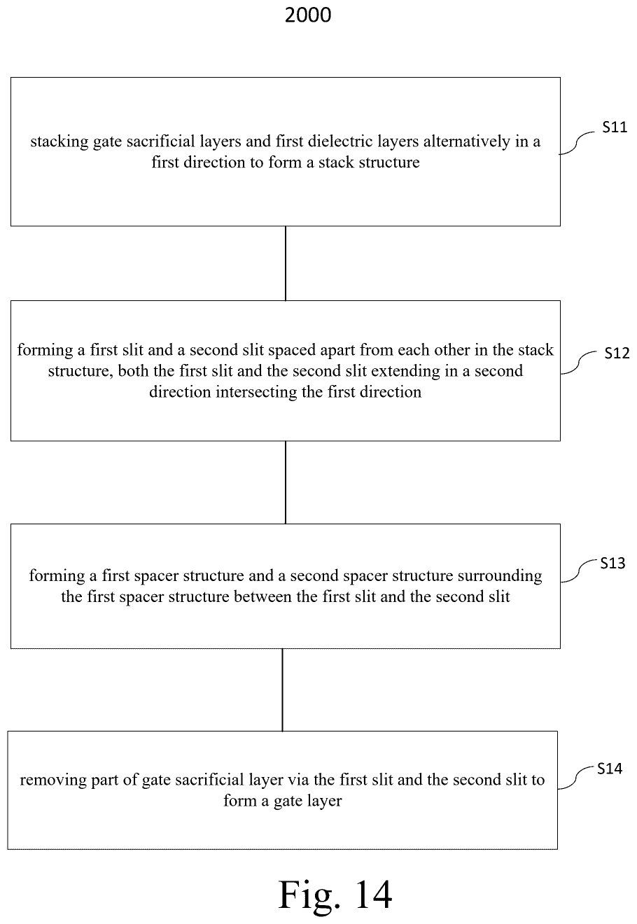

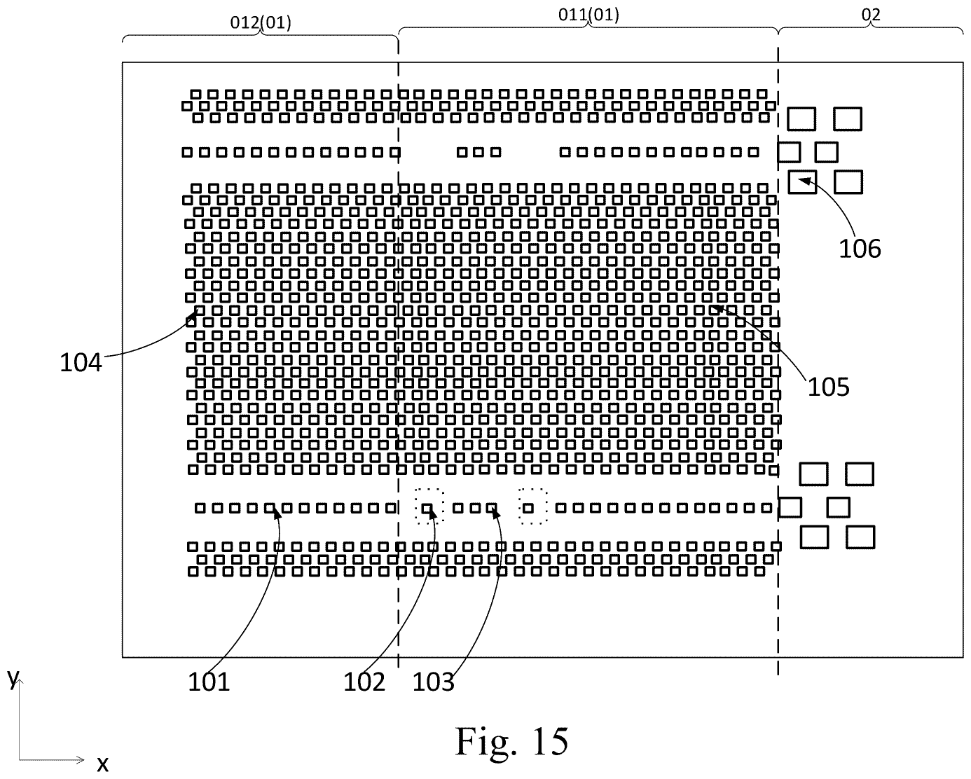

FIG. 14 is a flow chart of a method 2000 of fabricating a semiconductor device, according to an implementation of the present disclosure. FIGS. 15-31 are process diagrams of a method 2000 of fabricating a semiconductor device, according to an implementation of the present disclosure, respectively.

As shown in FIG. 14, the method 2000 of fabricating a semiconductor device may include, e.g., operations S11-S14.

At operation S11, gate sacrificial layers and first dielectric layers may be stacked alternatively in a first direction to form a stack structure;

At operation S12, a first slit and a second slit are formed spaced apart from each other in the stack structure, both the first slit and the second slit extending in a second direction intersecting the first direction;

At operation S13, a first spacer structure and a second spacer structure are formed surrounding the first spacer structure between the first slit and the second slit;

At operation S14, partial gate sacrificial layer may be removed via the first slit and the second slit to form the gate layer.

Processes of operations of the above-described method 2000 in implementations of the present disclosure will be described in detail below in connection with FIGS. 15-31.

### Operation S11

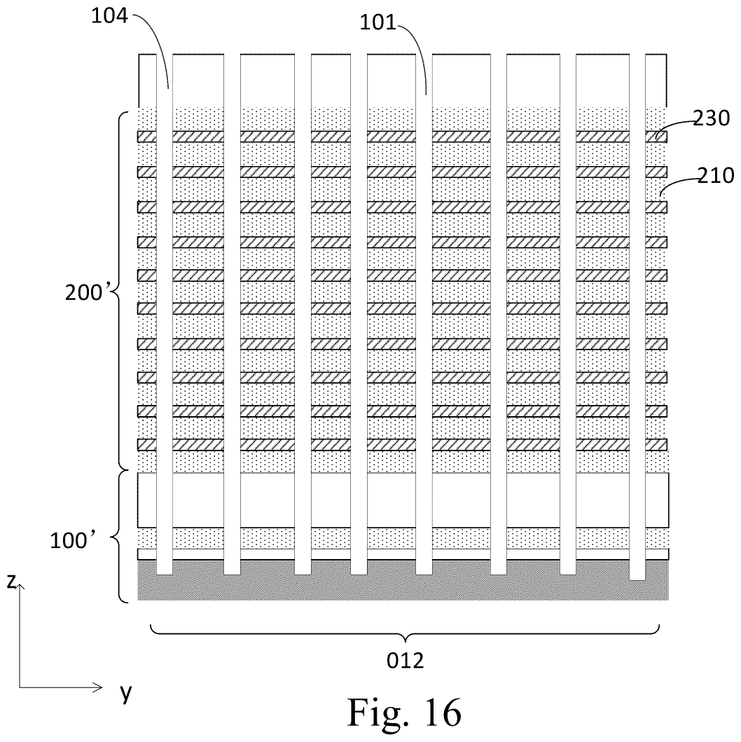

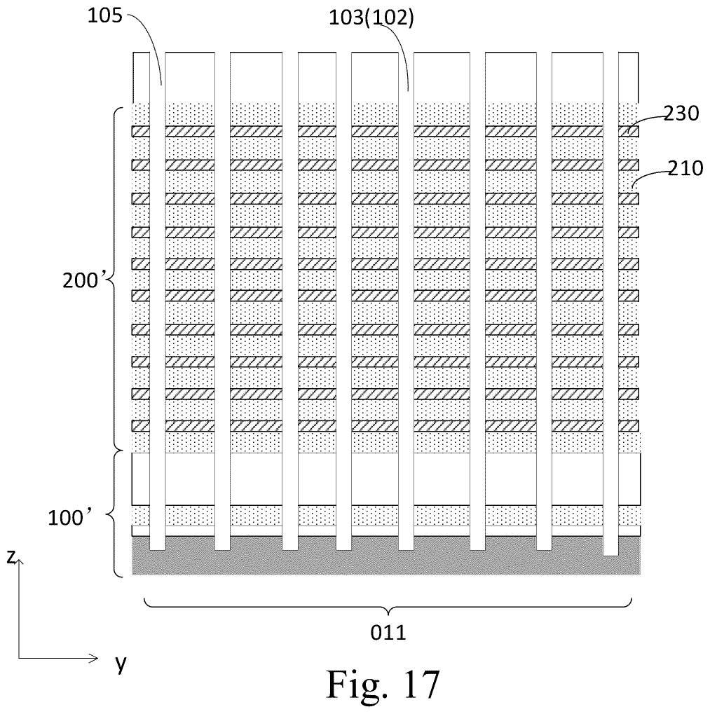

FIG. 15 is a top view of the structure after forming the first hole 101, according to an implementation of the present disclosure. FIG. 16 is a cross-sectional diagram of the structure after forming the first hole 101, according to an implementation of the present disclosure. FIG. 17 is a cross-sectional diagram of the structure after forming the first hole 101, according to an implementation of the present disclosure.

As shown in FIGS. 14-17, operation S11 of stacking gate sacrificial layers and first dielectric layers alternatively in the first direction to form a stack structure may include for example: providing a substrate 100′; and stacking first dielectric layers 210 and gate sacrificial layers 230 alternatively to form the stack structure 200′.

In particular, in an implementation of the present disclosure, the material for fabricating the substrate 100′ may be selected from any suitable semiconductor material such as single crystalline silicon (Si), single crystalline germanium (Ge), silicon germanium (GeSi), silicon carbide (SiC), silicon-on-insulator (SOI), germanium-on-insulator (GOI), or III-V compounds such as gallium arsenide. Further, the substrate 100′ may be single crystalline silicon.

In an implementation of the present disclosure, the substrate 100′ may be a composite substrate to provide support for device structures thereon. A plurality of layers of different materials may be disposed successively with a thin film deposition process such as chemical vapor deposition (CVD), physical vapor deposition (PVD), atomic layer deposition (ALD) or any combination thereof to form the substrate 100.

The substrate 100′ may include a substrate sacrificial layer (not shown) for subsequently forming the semiconductor connection layer (for example, forming the second semiconductor layer in subsequent operations etc.). The substrate sacrificial layer may include a single layer, a plurality of layers or a suitable composite layer. For example, the substrate sacrificial layer may include any one or more of a silicon oxide layer, a silicon nitride layer and a silicon oxynitride layer. As an option, the substrate sacrificial layer may be a high dielectric constant dielectric layer. As another option, the substrate sacrificial layer may include a first dielectric layer (not shown), a sacrificial layer (not shown) and a second dielectric layer (not shown) disposed successively, where the first and second dielectric layer may be silicon nitride layer and the sacrificial layer may be a silicon oxide layer. Optionally, the sacrificial layer may also be single crystalline silicon or polycrystalline silicon. In particular, in an implementation of the present disclosure, an example material for forming the sacrificial layer may be polysilicon. As another option, the substrate sacrificial layer may include any one or more of dielectric material, semiconductor material and conductive material.

Partial regions of the substrate 100′ may be further formed as doped well regions by ion implanting or diffusing N type or P type dopants. The dopant may include any one of or combination of phosphorous (P), arsenic (As) and antimony (Sb). In some implementations of the present disclosure, the well regions may be fabricated with the same dopant or different dopants. Further, the doping concentrations of the well regions may be the same or different, which is not limited in the present disclosure.

After forming the substrate 100′, it is possible to form a stack structure 200′ on a side of the substrate 100′ with one or more thin film deposition processes including, but not limited to chemical vapor deposition (CVD), physical vapor deposition (PVD), atomic layer deposition (ALD) or any combinations thereof, which is not limited in the present disclosure.

The stack structure 200′ may include a plurality pairs of first dielectric layers 210 and gate sacrificial layers 230 stacked alternatively. For example, the stack structure 200′ may include 64, 128 or more than 128 pairs of first dielectric layers 210 and gate sacrificial layers 230.

In other words, it is possible to stack the first dielectric layers 210 and the gate sacrificial layers 230 in the first direction (z-direction) to form the stack structure 200′. In some implementations, the first dielectric layer 210 and the gate sacrificial layer 230 may include the first dielectric material and a second dielectric material different from the first dielectric material, respectively. Exemplary materials for forming the first dielectric layer 210 and the gate sacrificial layer 230 may include silicon oxide and silicon nitride, respectively. The silicon oxide layer may serve as separating stack layer while the silicon nitride layer may serve as sacrificial stack layer. Subsequently, it is possible to etch off partial sacrificial stack layer and replace the etched partial sacrificial stack layer with a conductor layer including conductive material to form the gate conductive layer of the 3D memory.

The method of fabricating a single dielectric stack structure has been illustrated above. In fact, as the storage capacity demand for semiconductor device such as 3D memory increases, the number of storage stack layers increases gradually. In order to break the process limits, it is also possible to use double stack technology or multi-stack technology to form the dielectric stack structure by successively stacking a plurality of sub-dielectric stack structures in the stacking direction of the dielectric stack structure, where each sub-dielectric stack structure may include a plurality of first dielectric layers and gate sacrificial layers disposed alternatively. The number of layers of each sub-dielectric stack structure may be the same or different. Since the contents and structures involved in the forgoing description of the fabrication process of the single dielectric stack structure may be fully or partially applicable to the dielectric stack structure including a plurality of sub-dielectric stack structures as described herein, no repetition will be made to the related or similar description. Nevertheless, one skilled in the art should understand that it is possible to proceed to subsequent fabrication process based on the multi-dielectric stack structures or single dielectric stack structure.

As shown in FIG. 15, the stack structure 200′ may include an array region 01 and a connection region 02 arranged adjacently in x-direction, where the array region 01 may include a first sub-region 011 and a second sub-region 012 adjacent in x-direction, and the first sub-region 011 is closer to the connection region 02 than the second sub-region 012. The array region 01 may be used to subsequently form the first channel structure having storage function and the connection region 02 may be used to subsequently form the contact structure that may be connected with the subsequently formed gate layer and allow the gate layer to be connected with external circuits via the contact structure.

### Operation S12

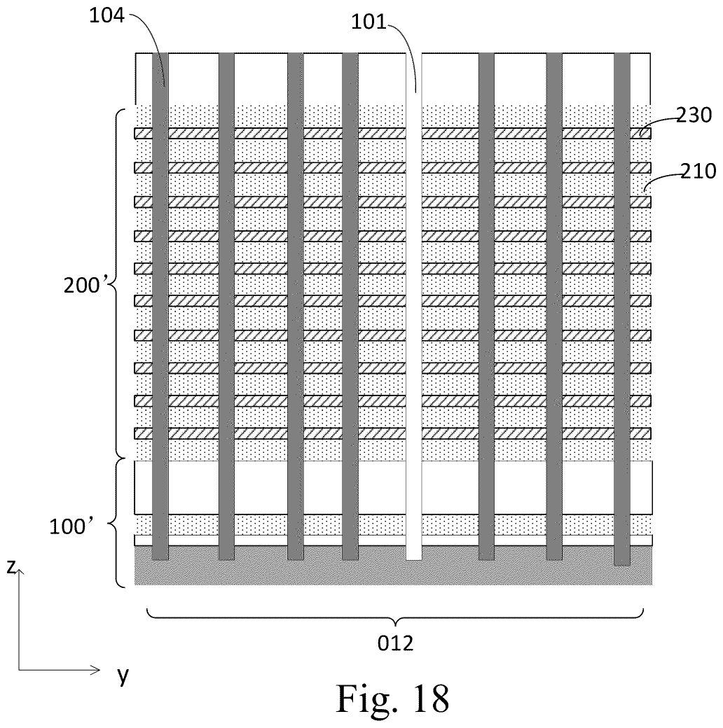

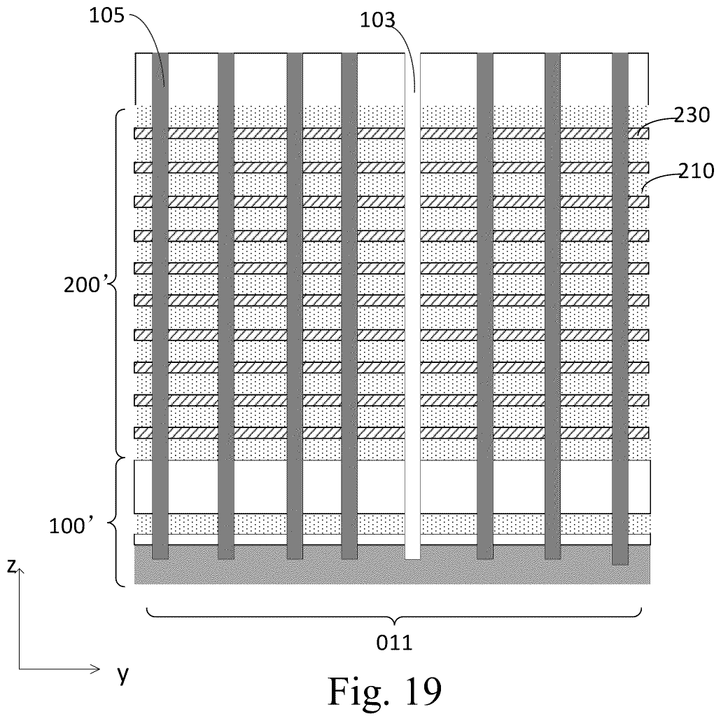

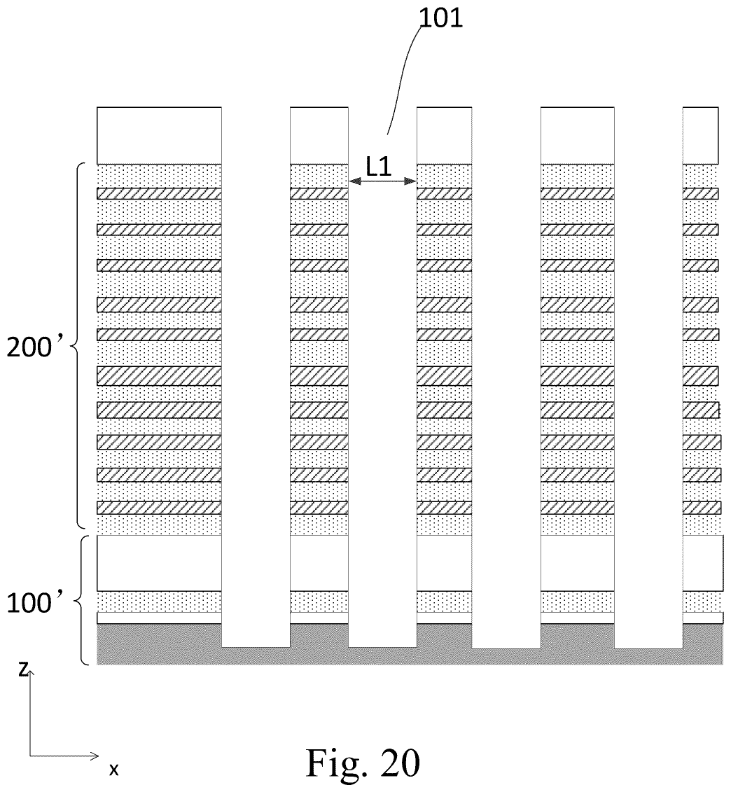

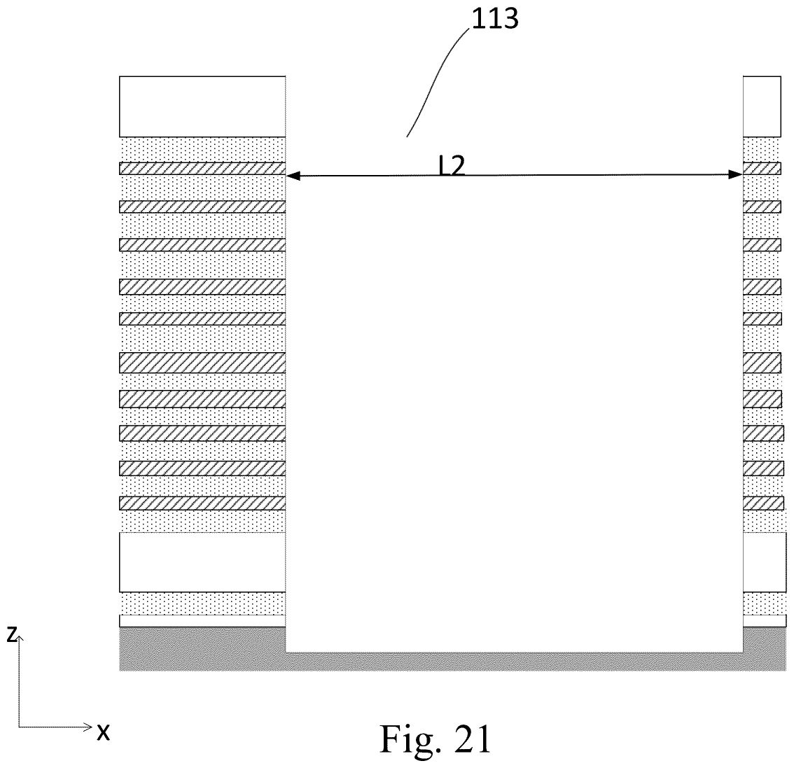

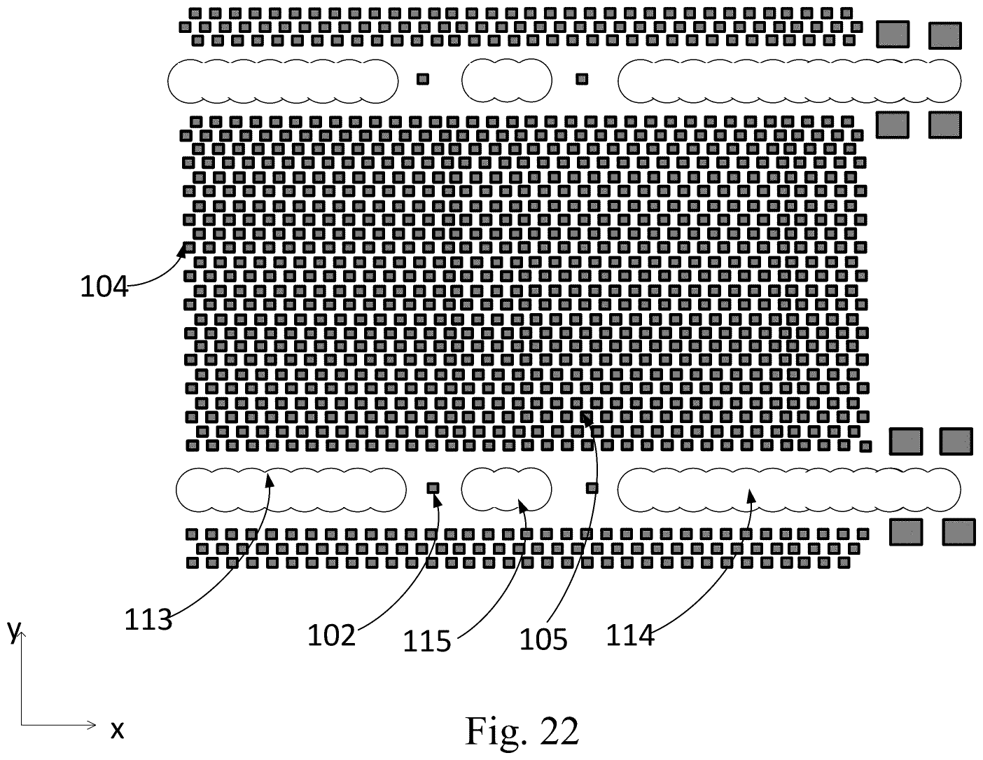

FIG. 18 is a cross-sectional diagram of the structure after filling the first channel hole 104, according to an implementation of the present disclosure. FIG. 19 is a cross-sectional diagram of the structure after filling the second channel hole 105, according to an implementation of the present disclosure. FIG. 20 is a cross-sectional diagram of the structure after forming the first hole 101, according to an implementation of the present disclosure. FIG. 21 is a cross-sectional diagram of the structure after forming the first slit 113, according to an implementation of the present disclosure. FIG. 22 is a cross-sectional diagram of the structure after forming the second slit 114, according to an implementation of the present disclosure.

As shown in FIGS. 15-22, operation S12 of forming a first slit and a second slit spaced apart from each other in the stack structure (both the first slit and the second slit extending in the second direction intersecting the first direction) may include, e.g., forming first holes 101 penetrating through the stack structure 200′ in the first direction, where the plurality of first holes 101 are arranged with intervals in the second direction (x-direction); and at least a part of the stack structure 200′ located between adjacent first holes 101 in x-direction is removed to form the first slit 113 and the second slit 114.

In particular, referring to FIGS. 15-17, in some implementations of the present disclosure, the method 2000 of fabricating the semiconductor device further includes, e.g., forming channel holes in the process of forming the first holes 101, where the channel holes include a first channel hole 104 and a second channel hole 105.

The completed semiconductor device may include a first channel structure and a second channel structure, where the first channel hole 104 may be used to form the first channel structure, and the second channel hole 105 may be used to form the second channel structure.

Furthermore, the completed semiconductor device may include a third channel structure. Therefore, as an option, the third channel hole 106 for forming the third channel structure may also be formed in the process of forming the first hole 101.

Furthermore, in some implementations of the present disclosure, the completed semiconductor device may include a first spacer structure and a second spacer structure. Therefore, the first opening 102 for forming the first spacer structure and the second hole 103 for forming the second spacer structure may also be formed in the process of forming the first hole 101.

In other words, in some implementations of the present disclosure, gate line slits containing the gate line isolation structure, such as first slit 113 and second slit 114 may be formed in operations. The first holes 101 that are formed first may be formed together with “deep holes” desired for other structures in the semiconductor device, and then a plurality of first holes 101 are communicated to form the first slit 113 and second slit 114 by “hole expanding” process. By forming various holes of different structures in the semiconductor device such as the first channel hole, the second channel hole and the first holes in the same process, it is possible to effectively reduce the number of etching processes used to form high aspect ratio structures, which in turn reduce the difficulty of fabricating the semiconductor device and the costs of fabricating the semiconductor device.

Furthermore, various holes of different structures in the semiconductor device may be fabricated with the same mask since they are formed in the same process, which may improve overlay accuracy in the etching process, reduce the overlay error and allow the completed semiconductor device to have high overall performance.

Optionally, a plurality of “deep holes”, such as first hole 101, first opening 102, second hole 103, first channel hole 104, second channel hole 105 and third channel hole 106, may be formed in the stack structure 200′ by for example dry etching process or a combination of dry etching process and wet etching process, or by implementing other manufacturing processes such as patterning processes including photolithography, cleaning and chemical mechanical polishing.

Optionally, the plurality of “deep holes” formed in the stack structure 200′ may have the same depth in z-direction, which may simplify the difficulty of etching process used to form high aspect ratio structures.

Furthermore, referring to FIG. 15, in the direction intersecting z-direction (e.g., x-direction or y-direction), the size of the third channel hole 106 may be greater than or equal to the size of the first channel hole 104. Optionally, in the direction intersecting z-direction, the size of the third channel hole 106 may be greater than or equal to the size of the second channel hole 105. Optionally, in the direction intersecting z-direction, the size of the first hole 101 may be greater than or equal to the size of the first channel hole 104. Optionally, in the direction intersecting z-direction, the size of the first hole 101 may be equal to the size of the first opening 102 or the second hole 103.

In addition, the first opening 102 may include at least one of a “hole” extending in z-direction and a “trench” extending in x-direction.

In other words, in the completed semiconductor device, the second spacer structure surrounds the first spacer structure, which may improve the stress of the part of the stack structure at which the spacer structures are located, reduce the cases in which topology of multiple channel structures corresponding to spacer structures shift, thereby improving the uniformity and consistency of the multiple channel structures and improving the comprehensive performance of semiconductor device. In order to optimize the above effects and improve the stress in particular direction in the region in which the second spacer structure resides, the size of the first spacer structure in x-direction may be greater than the size of the first spacer structure in y-direction. Therefore, in the process of fabricating the semiconductor device, the first opening 102 that contains the first spacer structure may be a “hole” or “trench” having a high aspect ratio structure, where the “a hole extending in z-direction” may be understood as a 2D pattern with a circular cross section in a direction perpendicular to its extension direction, and the “a trench extending in x-direction” may be understood as an asymmetrical 2D pattern with an oval or rectangular cross section in a direction perpendicular to its own extension direction.

Optionally, suitable shapes, sizes and locations of “holes” or “trenches” may be selected for any one of the above-described “deep holes” according to the architecture of the completed semiconductor device. For example, the “hole” or “trench” shown in FIG. 15 has a rectangular cross-sectional shape in x-y plane.

Optionally, the first opening 102 and the second hole 103 may be arranged with an interval in the first sub-region 011 of the stack structure 200′ in x-direction. Furthermore, the plurality of second channel holes 105 may be located in the first sub-region 011 of the stack structure 200′. The plurality of first channel holes 104 may be located in the second sub-region 012 of the stack structure 200′. The plurality of third channel holes 106 may be located in the connection region 02 of the stack structure 200′.

Referring to FIGS. 18-22, after forming the first hole 101, it is possible to remove at least a part of the stack structure 200′ located between adjacent first holes 101 in x-direction to form the first slit 113 and the second slit 114.

In particular, it is possible to fill a hole sacrificial layer in the first opening 102, the first channel hole 104, the second channel hole 105 and the third channel hole 106 with thin film deposition processes such as chemical vapor deposition (CVD), physical vapor deposition (PVD), atomic layer deposition (ALD) or any combinations thereof. The hole sacrificial layer may include a carbon containing material layer. The hole sacrificial layer may be formed of a material having a high deposition speed to facilitate filling the above-described plurality of “deep holes” quickly. The hole sacrificial layer should be of any material with a high dry-etch selectivity with respect to the first dielectric layer 210 and the gate sacrificial layer 230 to facilitate removing in subsequent operations.

Thereafter, a plurality of first holes 101 may be communicated to form a first slit 113 and a second slit 114 by “expanding” the first holes with for example dry etching process or a combination of dry etching process and wet etching process, or by implementing other manufacturing processes such as patterning processes including photolithography, cleaning and chemical mechanical polishing.

As an option, it is possible to expand or extend the first holes 101 in multiple directions in operations to form the first slit 113 and the second slit 114.

Referring to FIGS. 20 and 21, considering forming the first slit 113 as an example, it is possible to remove partial stack structure 200′ in the radial direction of the first hole 101 such that the size in x-direction of the part of the first hole 101 in the stack structure 200′ is enlarged from L1 to L2, and it is possible to continuously remove partial substrate 100′ in the radial direction of the first hole 101 such that the size in x-direction of the part of the first hole 101 in the substrate 100′ is also enlarged from L1 to L2, thereby forming the first slit 113, where the size of the first slit 113 in x-direction may be L1.

Furthermore, optionally, it is also possible to only remove partial stack structure 200′ in the radial direction of the first hole 101 such that the size in x-direction of the part of the first hole 101 in the stack structure 200′ is enlarged from L1 to L2. Thus, it is possible to omit the operation of “removing partial substrate 100′ in the radial direction of the first hole 101”. Considering the functions of the first slit 113 and the second slit 114 in removing partial gate sacrificial layer 230 (as shown in FIG. 19), both the first slit 113 and the second slit 114 can penetrate through the stack structure 200′ in z-direction without extending into the substrate 100′.

Furthermore, referring to FIGS. 15 and 22, as an option, it is possible to “expand” the second hole 103 in the process of forming the first slit 113 and the second slit 114 by “hole expanding” to communicate a plurality of second holes 103 arranged with intervals in x-direction, thereby forming communicated second openings 115.

It is to be noted that other layer structures (referring to FIG. 19) of the stack structure 200′, such as the gate sacrificial layer 230 (referring to FIG. 19) are omitted to facilitate observing the shapes and locations of “deep holes” in FIGS. 15 and 22.

Additionally, as shown in FIG. 22, after forming the first slit 113 and the second slit 114, it is possible to remove the hole sacrificial layers in the first opening 102, the first channel hole 104, the second channel hole 105 and the third channel hole 106 with for example dry etching process or a combination of dry etching process and wet etching process, or by implementing other manufacturing processes such as patterning processes including photolithography, cleaning and chemical mechanical polishing, thereby facilitating subsequent operations.

### Operation S13

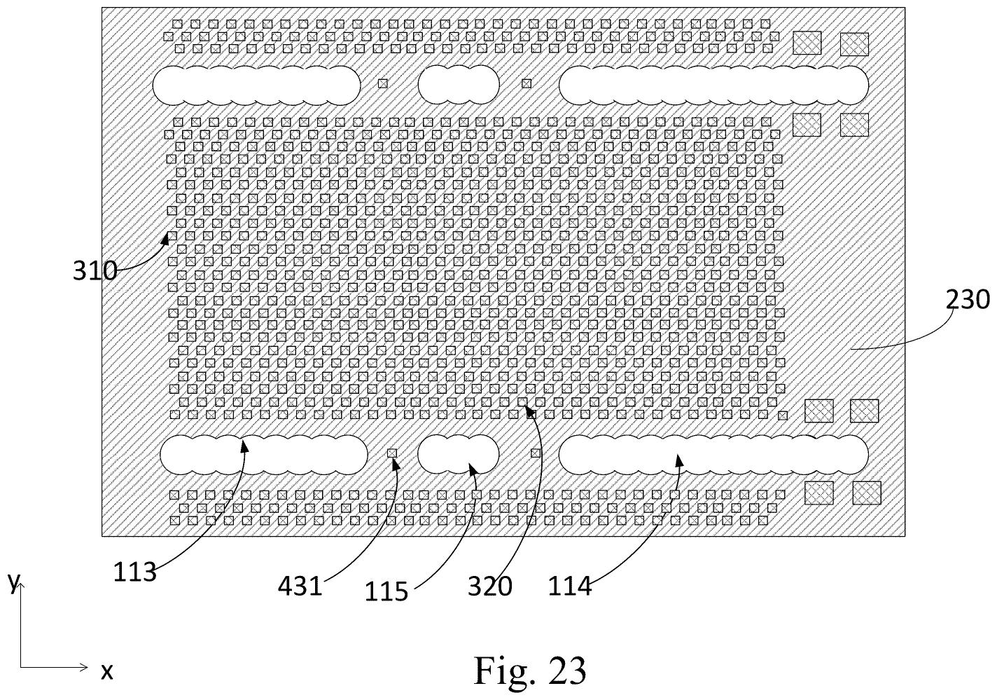

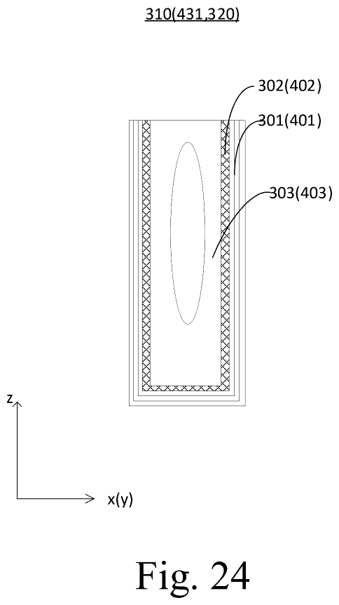

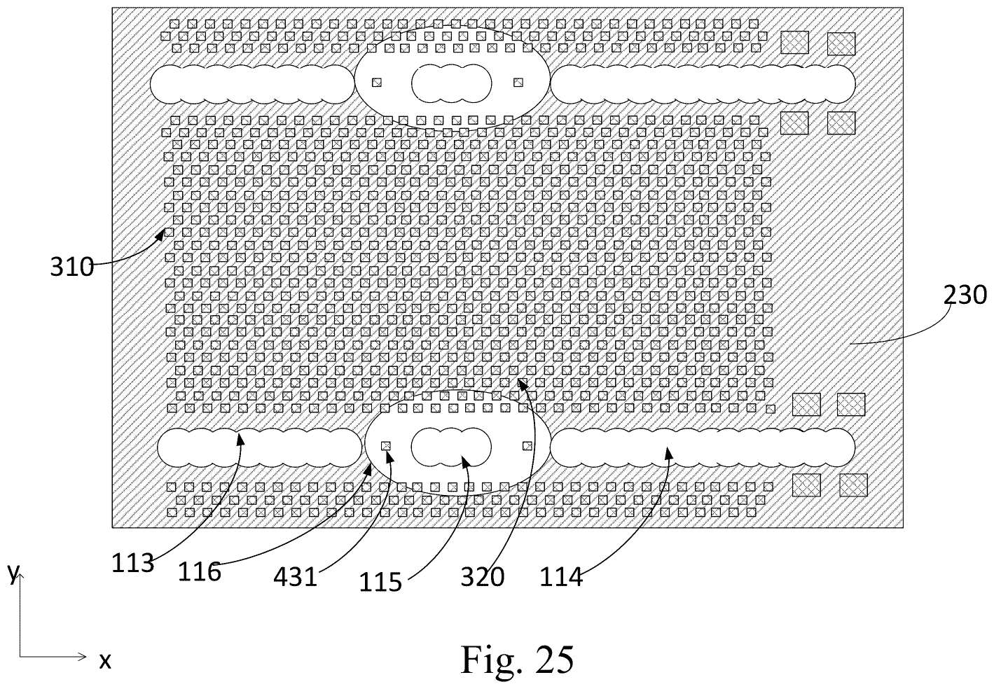

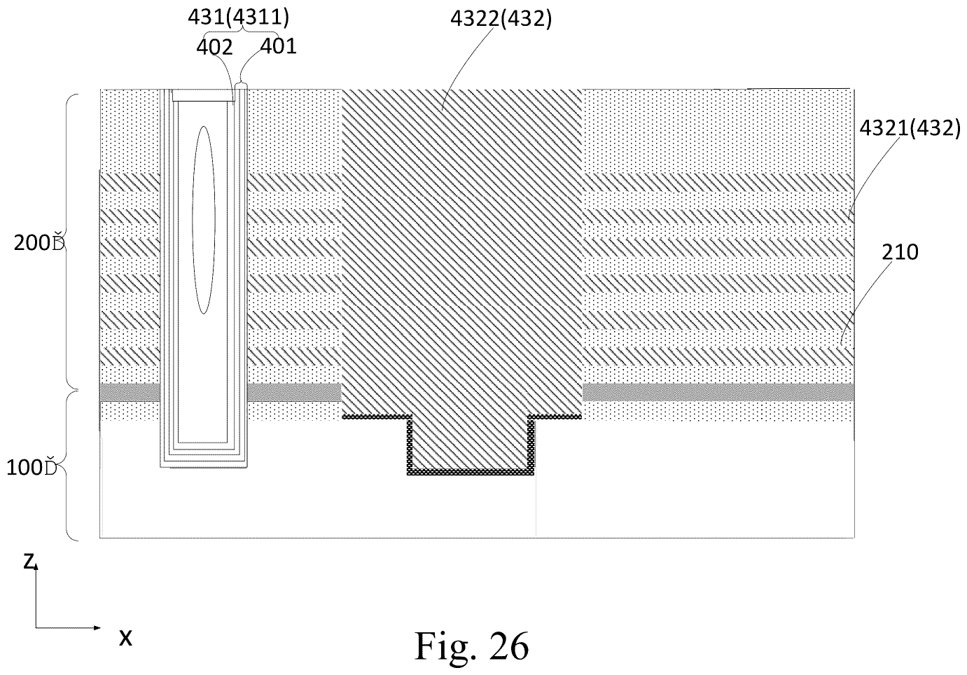

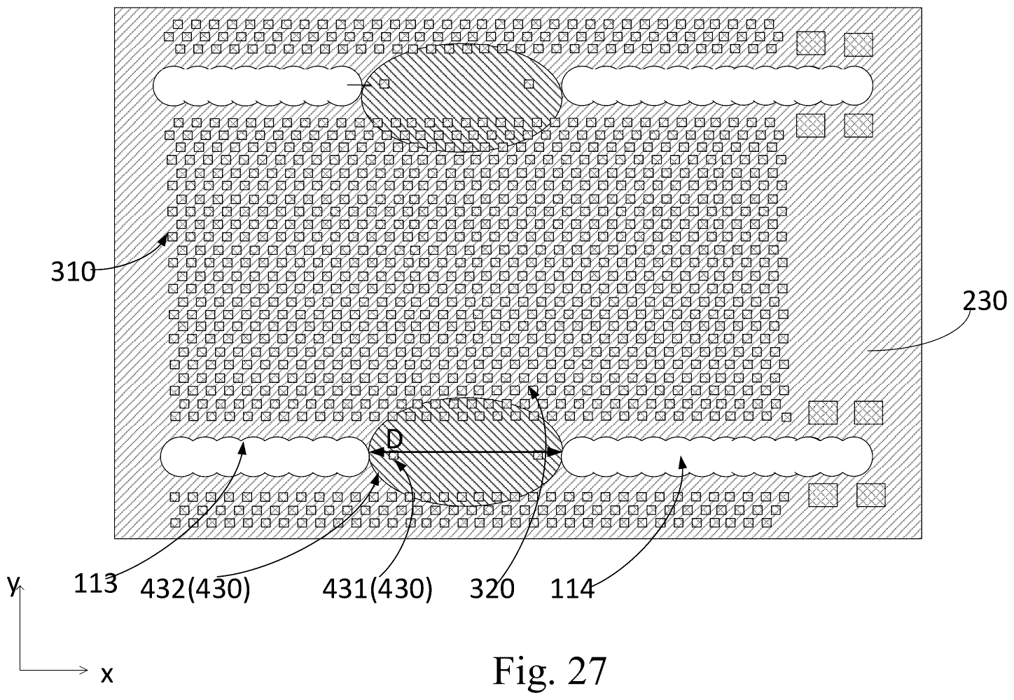

FIG. 23 is a top view of the structure after forming the first spacer structure 431, according to an implementation of the present disclosure. FIG. 24 is a cross-sectional diagram of the first spacer structure 431, according to an implementation of the present disclosure. FIG. 25 is a top view of the structure after forming the separating void 116, according to an implementation of the present disclosure. FIG. 26 is a cross-sectional diagram of the structure after forming the second spacer structure 432, according to an implementation of the present disclosure. FIG. 27 is a top view of the structure after forming the second spacer structure 432, according to an implementation of the present disclosure.

As shown in FIGS. 22-27, operation S13 of forming a first spacer structure and a second spacer structure surrounding the first spacer structure between the first slit and the second slit may include for example: forming the first spacer structure between the first slit and the second slit; and forming the second spacer structure.

In particular, as shown in FIGS. 22-24, in some implementations of the present disclosure, after forming the channel hole and the first opening 102, where the channel hole includes a first channel hole 104, a second channel hole 105 and a third channel hole 106, forming the first spacer structure 431 may include: forming a functional layer 301 in the channel hole and the first opening 102 and forming a channel layer 302 on the surface of the functional layer 301, where parts of the functional layer 301 and the channel layer 302 that fill in the first opening 102 form the first spacer structure 431.

In other words, in order to simplify the fabrication process of the semiconductor device and reduce the fabrication costs of the semiconductor device, the first spacer structure 431 may be formed in the same process as the first channel structure 310, the second channel structure 320 and the third channel structure (the above-described first channel structure 310, the second channel structure 320 and the third channel structure will be referred to as channel structures hereinbelow). In particular, it is possible to form the functional layer 301 of the channel structure and the first layer 401 of the first spacer structure 431 with the same material, both of which may include an oxide-nitride-oxide (ONO) structure. However, in some other implementations, both the functional layer 301 and the first layer 401 may also have a structure different from ONO configuration. Furthermore, both the channel layer 302 and the second layer 402 may be fabricated from semiconductor material such as poly-crystalline silicon or single crystalline silicon and may have conductive impurities. In addition, the channel structure may further include a channel filling dielectric layer 303, and the first spacer structure 431 may further include a third layer 403, both of which may include insulating dielectric material layer such as silicon oxide layer.

As shown in FIGS. 23, 25-27, after forming the communicated second opening 115, in some implementations of the present disclosure, forming the second spacer structure 432 may include: removing partial gate sacrificial layer 230 via the communicated second opening 115 to form the separating void 116; and filling the communicated second opening 115 and separating void 116 with insulating dielectric material to form the second spacer structure 432.

In the subsequent process of forming the gate layer with gate last process, it is possible to remove partial gate sacrificial layer 230 with for example wet etch process, where the etchant and chemical precursor may be brought into contact with the gate sacrificial layer 230 and in turn remove partial gate sacrificial layer 230 to form the gate layer by means of the first slit 113 and the second slit 114. In this process, the first spacer structure 431 and the second spacer structure 432 may separate the first slit 113 and the second slit 114 so as to remove partial gate sacrificial layer 230 with the first slit 113 and the second slit 114, respectively. For example, while removing partial gate sacrificial layer 230 with the first slit 113, since the first slit 113 and the second slit 114 are separated by the first spacer structure 431 and the second spacer structure 432, etchant in the first slit 113 will not flow into the second slit 114, nor flow into the formed other structures via the second slit 114. Similarly, while removing partial gate sacrificial layer 230 with the second slit 114, since the first slit 113 and the second slit 114 are separated by the first spacer structure 431 and the second spacer structure 432, etchant in the second slit 114 will not flow into the first slit 113, nor flow into the formed other structures via the first slit 113. This allows removing partial gate sacrificial layer 230 step by step with the first slit 113 and the second slit 114 and reduces the cases in which formed other structures in the semiconductor intermediate are damaged, thereby in turn improving the comprehensive performance of the completed semiconductor device.

Furthermore, the extension size D of the second spacer structure 432 in the direction intersecting z-direction may satisfy: 400 nm≤D≤1500 nm. By reasonably controlling the extension length of the second spacer structure, it is possible to relatively increase the length of effective storage region in the completed semiconductor device and improve the storage capacity of the semiconductor device.

instance, as shown in FIGS. 23 and 25, it is possible to remove partial gate sacrificial layer 230 adjacent to the communicated second openings 115 to form the separating void 116 with for example dry etching process or a combination of dry etching process and wet etching process, or by implementing other manufacturing processes such as patterning processes including photolithography, cleaning and chemical mechanical polishing.

Thereafter, as shown in FIGS. 25-27, it is possible to fill an insulating dielectric material in the communicated second openings 115 and the separating voids 116 with one or more film deposition processes to form the second spacer structure 432.

The second spacer structure 432 includes a plurality of isolation layers 4321, where the isolation layers 4321 may be stacked alternatively with first dielectric layers 210 in z-direction and disposed in the same layer as gate sacrificial layer 230. Optionally, the material for the isolation layers 4321 may include any suitable insulating dielectric material. For example, the isolation layer 4321 includes an insulating dielectric material layer such as silicon oxide layer. As an option, the isolation layer 4321 may include the same insulating dielectric material layer as the first dielectric layer 210. In this case, there are still boundaries between the isolation layers 4321 and the first dielectric layers 210 since the isolation layer 4321 is formed with the insulating dielectric material filled in the separating voids 116 in a forming process different from the first dielectric layers 210. Furthermore, the second spacer structure 432 further includes an isolation post 4322 extending in z-direction and including the same insulating dielectric material as the isolation layers 4321.

### Operation S14

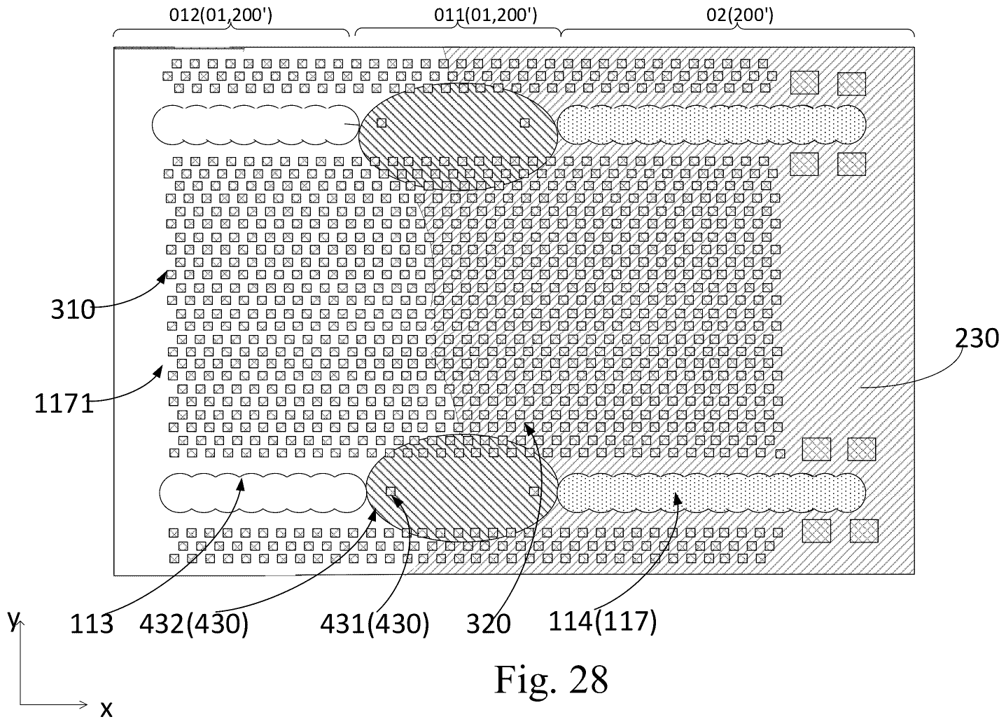

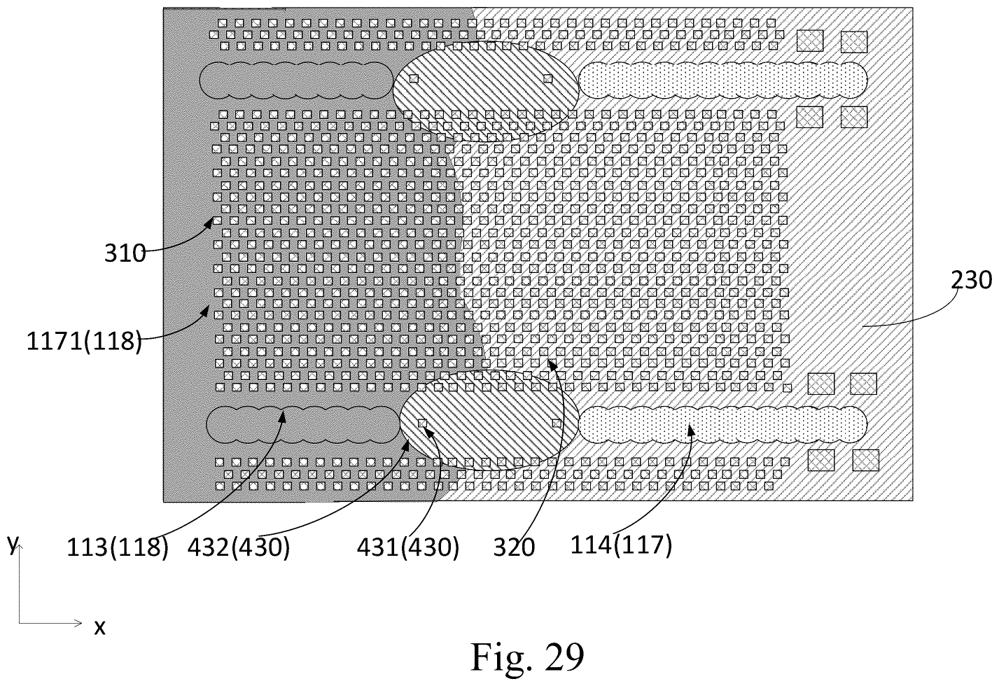

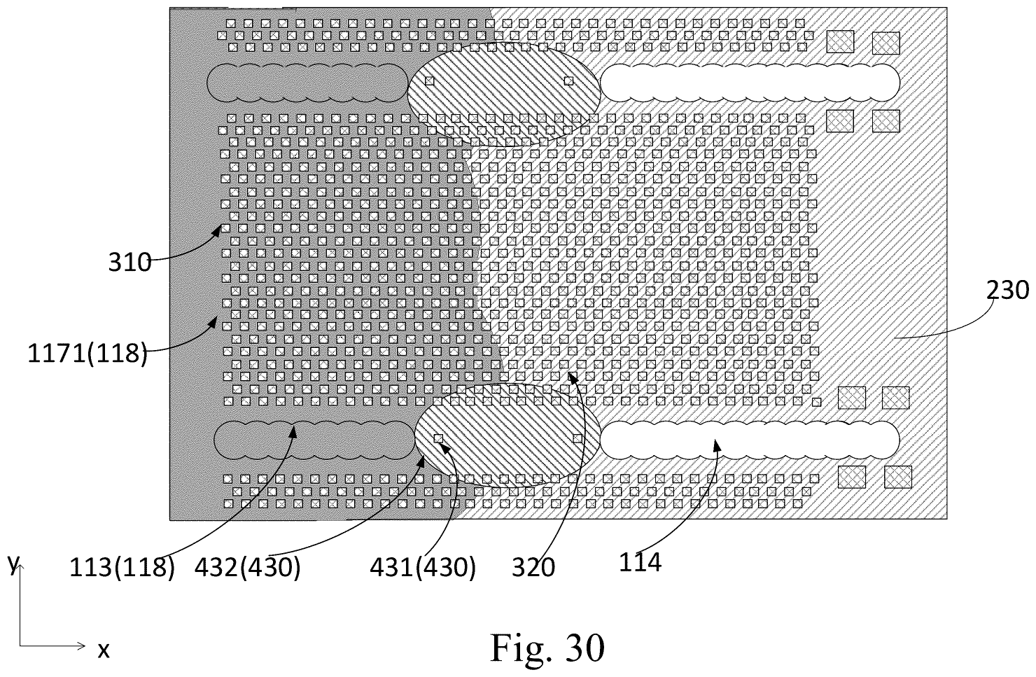

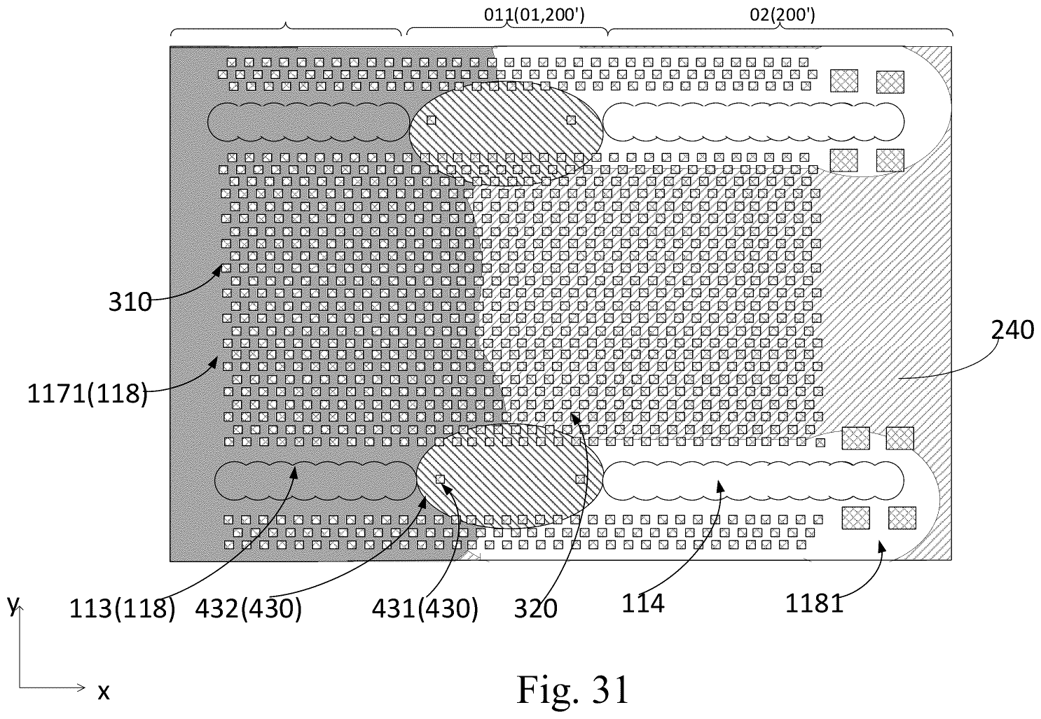

FIG. 28 is a top view of the structure after forming the first sacrificial layer 117, according to an implementation of the present disclosure. FIG. 29 is a top view of the structure after forming the second sacrificial layer 118, according to an implementation of the present disclosure. FIG. 30 is a top view of the structure after exposing the second slit 114, according to an implementation of the present disclosure. FIG. 31 is a top view of the structure after forming the second void 1181, according to an implementation of the present disclosure.

Referring to FIGS. 1, 27-31, operation S14 of removing partial gate sacrificial layer 230 via the first slit 113 and the second slit 114 to form the gate layer 220 may include for example: filling the second slit 114 with a first sacrificial layer 117 and removing partial gate sacrificial layer 230 via the first slit 113 to form the first void 1171; filling the first void 1171 and the first slit 113 with a second sacrificial layer 118; removing the first sacrificial layer 117 and removing partial gate sacrificial layer 230 via the second slit 114 to form a second void 1181 communicating with the first void 1171; and removing the second sacrificial layer 118 and forming the gate layer 220 in the first void 1171 and the second void 1181.

In particular, as shown in FIGS. 27-28, it is possible to fill the first sacrificial layer 117 in the second slit 114 with thin film deposition processes such as chemical vapor deposition (CVD), physical vapor deposition (PVD), atomic layer deposition (ALD) or any combinations thereof. Optionally, the first sacrificial layer 117 may include a semiconductor material layer such as poly-crystalline silicon or a carbon containing material layer. The first sacrificial layer 117 may be formed of a material having a high deposition speed to facilitate filling the above-described plurality of “deep holes” quickly. The hole sacrificial layer should be of any material with a high dry-etch selectivity with respect to the first dielectric layer 210 (as shown in FIG. 26) and the gate sacrificial layer 230 to facilitate removing in subsequent operations.

After forming the first sacrificial layer 117, it is possible to remove partial gate sacrificial layer 230 with for example wet etch process to form the first void 1171. The gate sacrificial layer 230 may include a part in the array region 01 of the stack structure 200′ and a part in the connection region 02 of the stack structure 200′. Optionally, the part of the gate sacrificial layer 230 in the array region 01 of the stack structure 200′ may be removed by means of the first slit 113. Furthermore, under the influence of the first spacer structure 431 and the second spacer structure 432 located between the first slit 113 and the second slit 114, the void wall of the first void 1171 facing the connection region 02 of the stack structure 200′ includes a curved surface including at least one of a concave surface and a convex surface.

As shown in FIGS. 28-29, after forming the first void 1171, it is possible to fill the second sacrificial layer 118 in the first void 1171 and the first slit 113 with thin film deposition processes such as chemical vapor deposition (CVD), physical vapor deposition (PVD), atomic layer deposition (ALD) or any combinations thereof. Optionally, the second sacrificial layer 118 may include a semiconductor material layer such as poly-crystalline silicon or a carbon containing material layer. The second sacrificial layer 118 may be formed of a material having a high deposition speed to facilitate filling the above-described plurality of “deep holes” quickly. The hole sacrificial layer should be of any material with a high dry-etch selectivity with respect to the first dielectric layer 210 (as shown in FIG. 26) and the gate sacrificial layer 230 to facilitate removing in subsequent operations. Furthermore, the second sacrificial layer 118 may include the same material as the first sacrificial layer 117.

As shown in FIGS. 29-30, it is possible to remove the first sacrificial layer 117 to expose the second slit 114 with for example dry etching process or a combination of dry etching process and wet etching process, or by implementing other manufacturing processes such as patterning processes including photolithography, cleaning and chemical mechanical polishing.

As shown in FIGS. 30-31, it is possible to remove partial gate sacrificial layer 230 with for example wet etch process to form the second void 1181 communicating with the first void 1171. Optionally, the part of the gate sacrificial layer 230 in the connection region 02 of the stack structure 200′ may be removed by means of the second slit 114. Furthermore, since the surfaces of side walls of the first slit 113 and the second slit 114 that contact the stack structure 200′ include curved surfaces, partial void walls of the first void 1171 and the second void 1181 include curved surfaces that include at least one of concave surface and convex surface.

As shown in FIGS. 1 and 31, after forming the first void 1171 and the second void 1181, it is possible to form the gate layer 220 in the first void 1171 and the second void 1181 with thin film deposition processes such as chemical vapor deposition (CVD), physical vapor deposition (PVD), atomic layer deposition (ALD) or any combinations thereof. The gate layers 220 may include a conductive material, for example, any one or combination of tungsten (W), cobalt (Co), copper (Cu), aluminum (Al), doped crystalline silicon or silicide.

Furthermore, the method 2000 of fabricating a semiconductor device according to an implementation of the present disclosure further includes forming an isolation dielectric layer (not shown) on inner walls of the first void 1171 and the second void 1181 and inner walls of the first slit 113 and second slit 114 with film deposition process such as chemical vapor deposition (CVD), physical vapor deposition (PVD), atomic layer deposition (ALD) or any combinations thereof. As an option, the isolation dielectric layer may be a high dielectric constant dielectric layer. Furthermore, it is also possible to form the adhesion layer (not shown) between the first dielectric layer 210 and the gate layer 220 or between the isolation dielectric layer and the gate layer 220 with film deposition process such as chemical vapor deposition (CVD), physical vapor deposition (PVD), atomic layer deposition (ALD) or any combinations thereof. For example, the adhesion layer may be for example a titanium nitride TiN layer.

In addition, with reference to FIGS. 1, 4 and 31, in some implementations of the present disclosure, after forming the gate layer 220, it is also possible to form the gate line isolation structure 400 by filling the first slit 113 and the second slit 114. In particular, it is possible to fill the gate line isolation layer 112 and the gate line filling layer 111 in the first slit 113 and the second slit 114, respectively, to form the gate line isolation structure 400 with thin film deposition processes such as chemical vapor deposition (CVD), physical vapor deposition (PVD), atomic layer deposition (ALD) or any combinations thereof. Insulating dielectric materials such as silicon oxide, silicon nitride and silicon oxynitride or semiconductor materials such as poly-crystalline silicon may be selected for the gate line filling layer 111, which is not limited in the present disclosure. After forming the gate line isolation structure 400 and the gate layer 220 in the stack structure 200′, the stack structure 200′ forms the stack structure 200.

Furthermore, it is to be noted that the gate layer 220 shown in FIG. 1 has a cross-sectional shape in x-y plane different from that of the first void 1171 and the second void 1181 shown in FIG. 31, where the x-y plane is the plane intersecting z-direction. In other words, the gate layer formed with the first void 1171 and the second void 1181 and the gate layer 220 shown in FIG. 1 have different cross-sectional shapes in x-y plane. As an option, it is possible to select cross-sectional shapes of the first void 1171 and the second void 1181 in x-y plane according to different settings of the architecture of the completed semiconductor device so as to effectively reduce the extension size of the gate layer, reduce the body resistance of the gate layer and in turn improve the integrity level of semiconductor device while enabling controlling channel structures 300 with external circuits.

Therefore, according to the method of fabricating the semiconductor device provided in at least one implementations of the present disclosure, the semiconductor device includes a stack structure, a gate line isolation structure, a first spacer structure and a second spacer structure, where the first spacer structure and the second spacer structure divide the gate line isolation structure into a first section and a second section arranged with an interval in the extension direction of the gate line isolation structure. The gate layer of the stack structure may be fabricated with gate last process. For example, a gate sacrificial layer is formed in advance. In the process of etching off the gate sacrificial layer with e.g., wet etching, the etchant and chemical precursor are brought into contact with gate sacrificial layer and in turn remove partial gate sacrificial layer to form the gate layer by means of gate line slits formed while forming the gate line isolation structure, such as the first gate line slit and the second gate line slit. The first spacer structure and the second spacer structure divide the gate line isolation structure into the first section and the second section; and similarly the first spacer structure and the second spacer structure separate the first slit and the second slit in the process of fabricating the semiconductor device, which can reduce the case in which excess etch solution flows into other structures that have been formed in the semiconductor intermediate via gate line slits in the process of removing gate sacrificial layer with gate last process in fabricating the semiconductor device, thereby improving comprehensive performance of the semiconductor device.

Moreover, the semiconductor device further includes a channel structure. The second spacer structure surrounds the first spacer structure, which may improve the stress of the part of the stack structure at which the first spacer structure and the second spacer structure are located, reduce the cases in which topology of multiple channel structures corresponding to them shift, thereby improving the uniformity and consistency of the multiple channel structures and improving the comprehensive performance of semiconductor device.

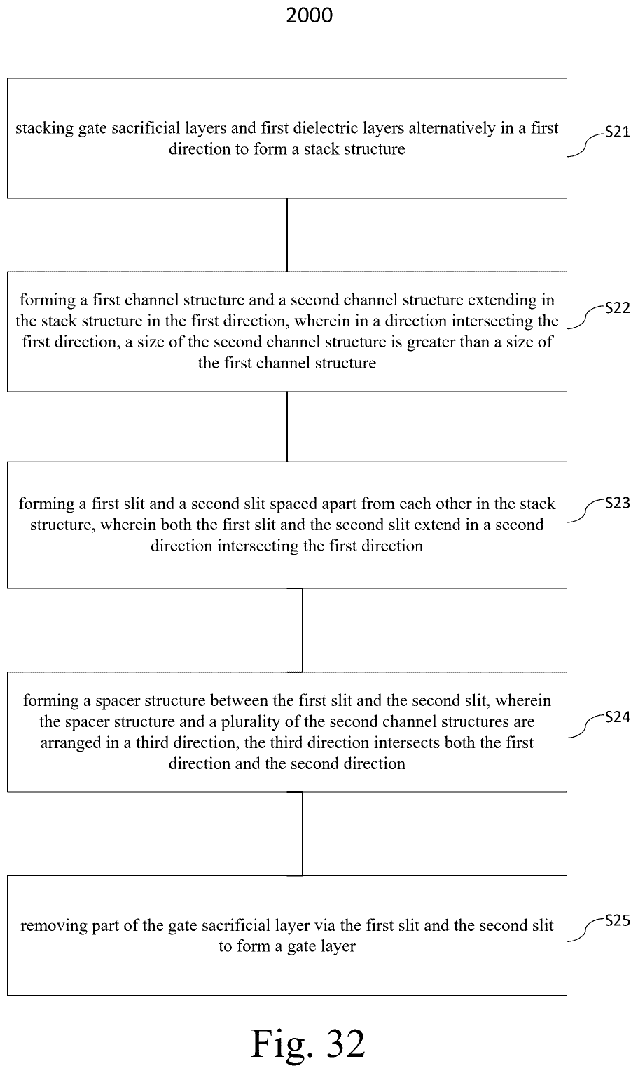

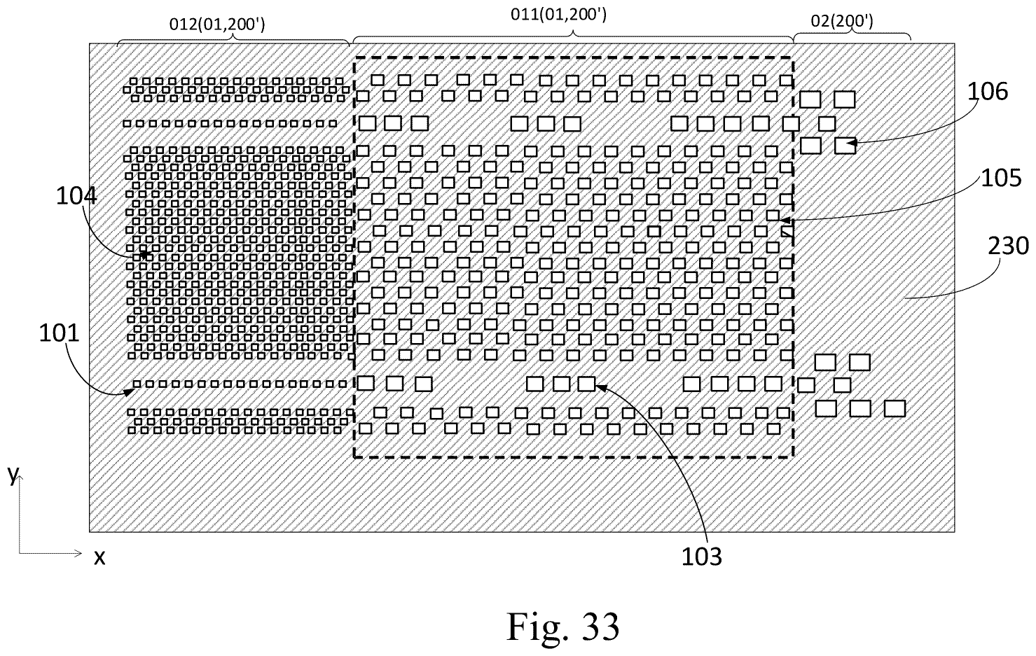

FIG. 32 is a flow chart of a method 2000 of fabricating a semiconductor device, according to another implementation of the present disclosure. FIGS. 33-41 are process diagrams of a method 2000 of fabricating a semiconductor device, according to another implementation of the present disclosure, respectively.

As shown in FIG. 32, the method 2000 of fabricating a semiconductor device may include operations S21-S25.

At operation S21, gate sacrificial layers and first dielectric layers may be stacked alternatively in a first direction to form a stack structure;

At operation S22, a first channel structure and a second channel structure may be formed extending in the stack structure in the first direction, where in a direction intersecting the first direction, the size of the second channel structure is greater than the size of the first channel structure;

At operation S23, a first slit and a second slit are formed spaced apart from each other in the stack structure, where both the first slit and the second slit extend in the second direction intersecting the first direction;

At operation S24, a spacer structure may be formed between the first slit and the second slit, where the spacer structure and the plurality of second channel structures are arranged in a third direction, the third direction intersects both the first direction and the second direction; and

At operation S25, a partial gate sacrificial layer may be removed via the first slit and the second slit to form the gate layer.

Since the contents involved in the method 2000 of fabricating the semiconductor device as described above in the implementation of one aspect of the present disclosure may be totally or partially applicable to the method of fabricating the semiconductor device as described in an implementation of another aspect, contents related or similar to them will not be described any longer. However, one skilled in the art will appreciate that the semiconductor device 1000 may be formed according to the method 2000 of fabricating the semiconductor device as described in the implementation of one aspect of the present disclosure (as shown in FIGS. 1-6) or according to the method 2000 of the semiconductor device as described in the implementation of another aspect of the present disclosure (as shown in FIGS. 7-13). Based on this, both the method 2000 of fabricating the semiconductor device as described in implementations of one aspect of the present disclosure and the method 2000 of fabricating the semiconductor device as described in implementations of another aspect of the present disclosure have the same beneficial effects as the semiconductor device 1000, which will not be described any longer.

Example operations of the above-described method 2000 in implementations of the present disclosure will be described in detail below in connection with FIGS. 33-41.

### Operation S22

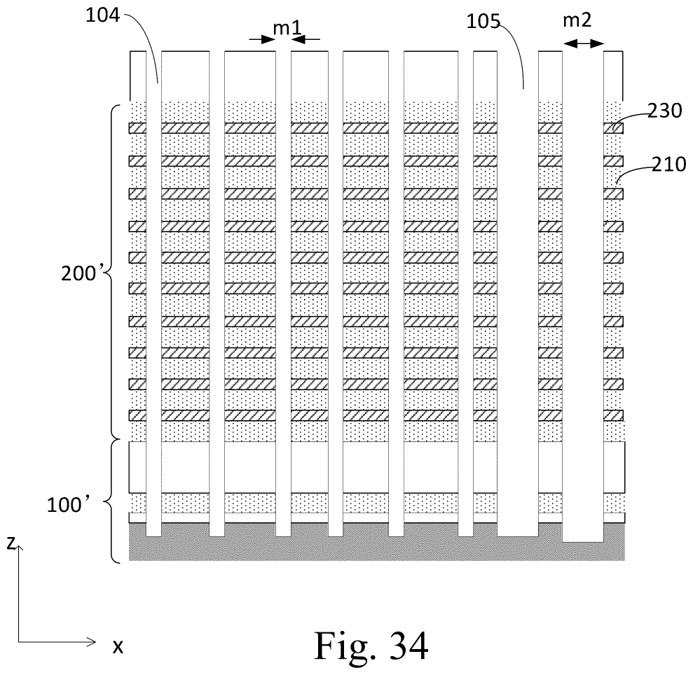

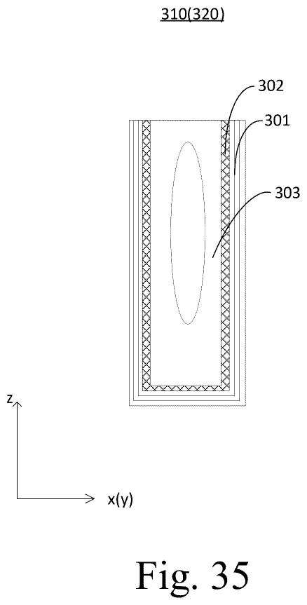

FIG. 33 is a top view of the structure after forming the first channel hole 104, according to an implementation of the present disclosure. FIG. 34 is a cross-sectional diagram of the structure after forming the first channel hole 104, according to an implementation of the present disclosure. FIG. 35 is a cross-sectional diagram of the first channel structure 310 and the second channel structure 320, according to an implementation of the present disclosure.

As shown in FIGS. 33-35, operation S22 of forming a first channel structure and a second channel structure extending in the stack structure in the first direction, where in a direction intersecting the first direction, the size of the second channel structure is greater than the size of the first channel structure may include for example: forming the first channel hole 104 and the second channel hole 105, where both the first channel hole 104 and the second channel hole 105 extend in the stack structure 200′ in z-direction, and in the direction intersecting z-direction (e.g., x-direction, y-direction), the size m2 of the second channel hole 105 is greater than the size m1 of the first channel hole 104; and forming a functional layer 301 in the first channel hole 104 and second channel hole 105, respectively, and forming a channel layer 302 on the surface of the functional layer 301.

As an option, the method 2000 of fabricating a semiconductor device may include forming gate line slits in operations. For example, the first holes 101 are formed first, then the plurality of first holes 101 are communicated to form the gate line slits by “hole expanding” process. The gate line slits may contain the gate line isolation structure in the semiconductor device.

Optionally, the first holes 101 may be formed together with “deep holes” of other structures in the semiconductor device 1000. For example, the first holes 101 may be formed in the same process as the first channel hole 104 and the second channel hole 105.

In particular, it is possible to remove partial stack structure 200′ and form the first holes 101, the first channel hole 104 and the second channel hole 105 with for example dry etching process or a combination of dry etching process and wet etching process, or by implementing other manufacturing processes such as patterning processes including photolithography, cleaning and chemical mechanical polishing.

The plurality of first holes 101 penetrate through the stack structure 200′ in z-direction, where the plurality of first holes 101 may be arranged with intervals in the second direction (x-direction). The plurality of first channel holes 104 penetrate through the stack structure 200′ in z-direction, where the plurality of first channel holes 104 may be arranged with intervals in the second direction (x-direction) and arranged with intervals in the third direction (y-direction). The plurality of second channel holes 105 penetrate through the stack structure 200′ in z-direction, where the plurality of second channel holes 105 may be arranged with intervals in the second direction (x-direction) and arranged with intervals in the third direction (y-direction).

Furthermore, the completed semiconductor device may further include a third channel structure. Therefore, the first hole 101 may be formed in the same process as the first channel hole 104, the second channel hole 105 and the third channel hole 106, where the third channel structure is formed in the third channel hole 106.

Optionally, in the direction intersecting z-direction (e.g., x-direction, y-direction), the size m2 of the second channel hole 105 may be equal to the size of the first hole 101. Optionally, in the direction intersecting z-direction (e.g., x-direction, y-direction), the size of the third channel hole 106 may be greater than or equal to the size m2 of the second channel hole 105.

Optionally, the stack structure 200′ may include an array region 01 and connection region 02 arranged adjacently in x-direction, where the array region 01 may include a first sub-region 011 and a second sub-region 012 adjacent in x-direction, and the first sub-region 011 is closer to the connection region 02 than the second sub-region 012. The plurality of first channel holes 104 may be located in the second sub-region 012; the plurality of second channel holes 105 may be located in the first sub-region 011; and the plurality of third channel holes 106 may be located in the connection region 02.

Optionally, the first holes 101, the first channel holes 104 and the second channel holes 105 may have the same extension size in z-direction to simplify the process difficulty of fabricating the plurality of “deep holes”.

By forming various holes of different structures in the semiconductor device such as the first channel hole, the second channel hole and the first hole in the same process, it is possible to effectively reduce the number of etching processes used to form high aspect ratio structures, which in turn reduce the difficulty of fabricating the semiconductor device and the costs of fabricating the semiconductor device.

Furthermore, various holes of different structures in the semiconductor device may be fabricated with the same mask since they are formed in the same process, which may improve overlay accuracy in the etching process, reduce the overlay error and allow the completed semiconductor device to have high overall performance.

### Operation S23

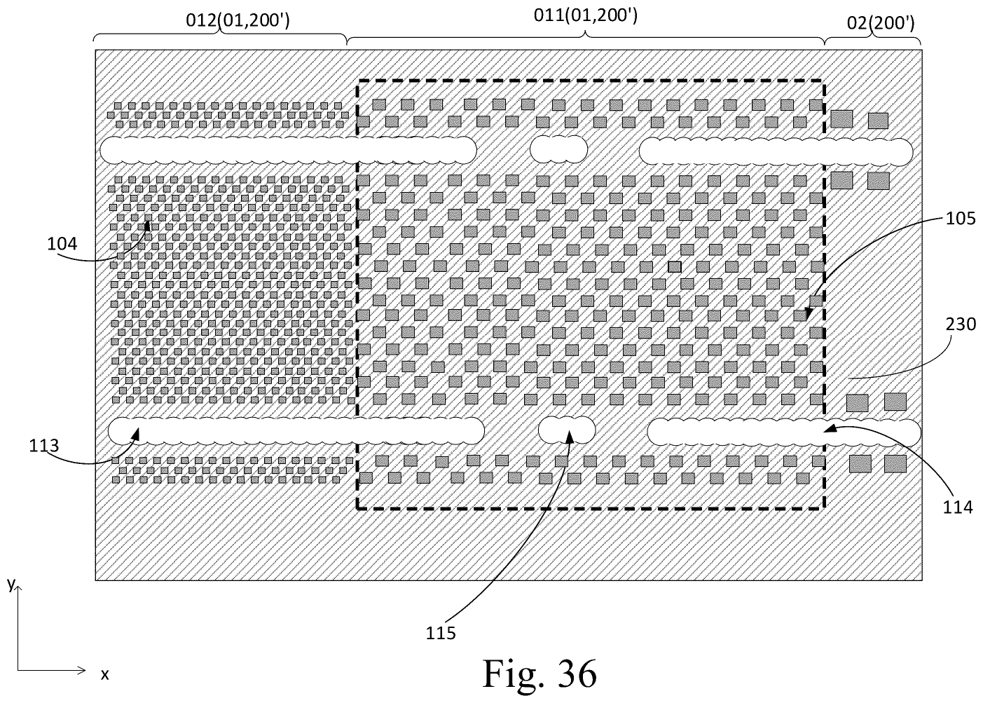

FIG. 36 is a top view of the structure after forming the first slit 113 and the second slit 114, according to an implementation of the present disclosure.

As shown in FIGS. 33, 34 and 36, operation S23 of forming a first slit and a second slit spaced apart from each other in the stack structure, where both the first slit and the second slit extend in the second direction intersecting the first direction may include for example: after forming the plurality of first holes 101, removing at least a part of the stack structure 200′ located between adjacent first holes 101 in x-direction to form the first slit 113 and the second slit 114.

In particular, it is possible to fill a hole sacrificial layer in the first channel hole 104, the second channel hole 105 and the third channel hole 106 with thin film deposition processes such as chemical vapor deposition (CVD), physical vapor deposition (PVD), atomic layer deposition (ALD) or any combinations thereof. The hole sacrificial layer may include a carbon containing material layer. The hole sacrificial layer may be formed of a material having a high deposition speed to facilitate filling the above-described plurality of “deep holes” quickly. The hole sacrificial layer should be of any material with a high dry-etch selectivity with respect to the first dielectric layer 210 and the gate sacrificial layer 230 to facilitate removing in subsequent operations.

Thereafter, a plurality of first holes 101 may be communicated to form a first slit 113 and a second slit 114 by “expanding” the first holes with for example dry etching process or a combination of dry etching process and wet etching process, or by implementing other manufacturing processes such as patterning processes including photolithography, cleaning and chemical mechanical polishing. As an option, it is possible to expand or extend the first holes 101 in multiple directions in operations to form the first slit 113 and the second slit 114.

### Operation S24

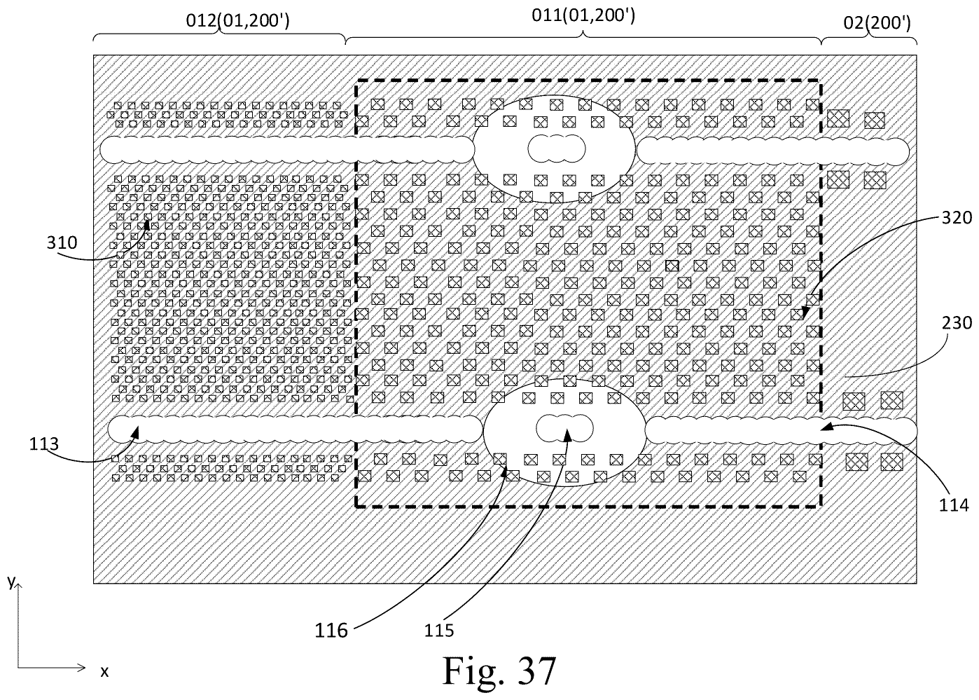

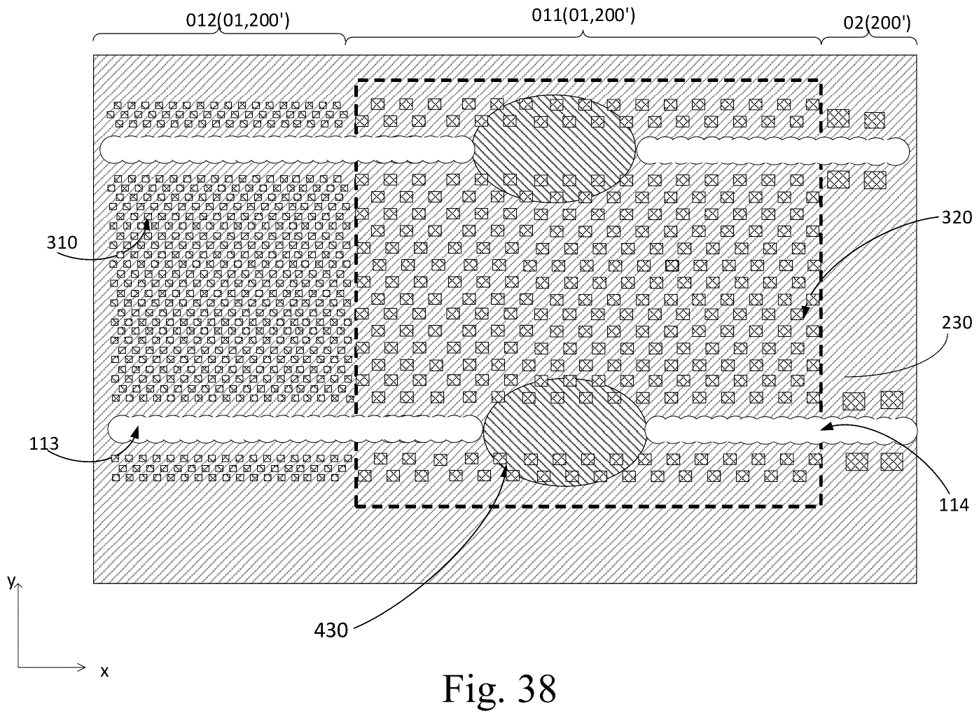

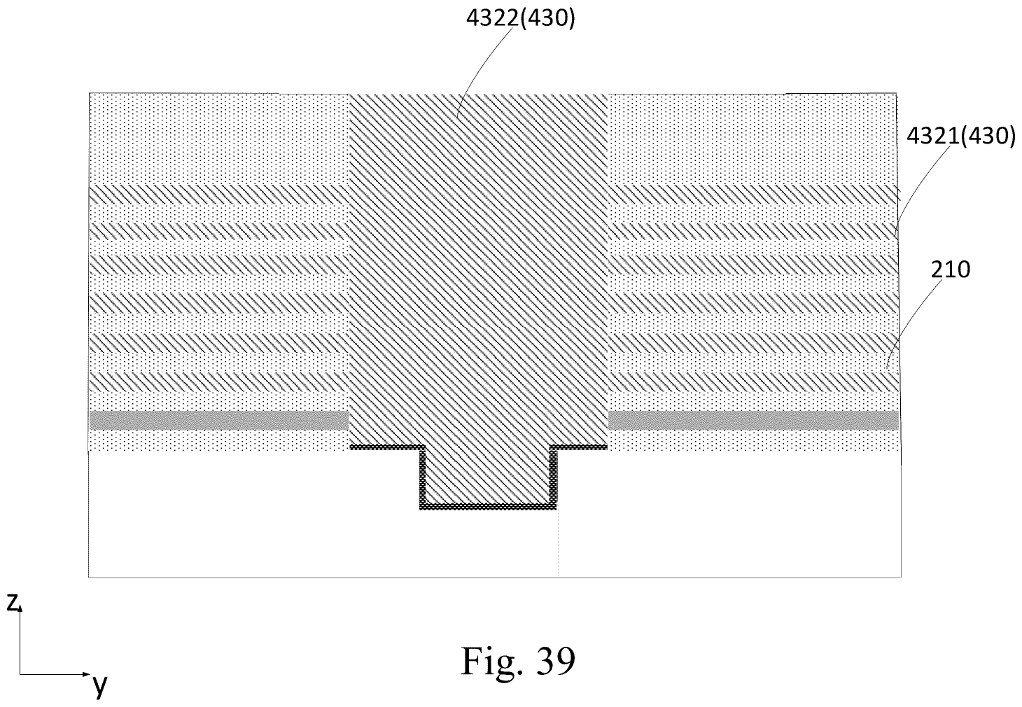

FIG. 37 is a top view of the structure after forming the second opening 115, according to an implementation of the present disclosure. FIG. 38 is a top view of the structure after forming the separating void 116, according to an implementation of the present disclosure. FIG. 39 is a cross-sectional diagram of the spacer structure 430, according to an implementation of the present disclosure.

As shown in FIGS. 33, 36-39, operation S24 of forming a spacer structure between the first slit and the second slit, where the spacer structure and the plurality of second channel structures are arranged in the third direction, the third direction intersects both the first direction and the second direction may include for example: forming a second opening 115 between the first slit 113 and the second slit 114; removing partial gate sacrificial layer 230 via the second opening 115 to form the separating void 116; and filling the second opening 115 and the separating void 116 with an insulating dielectric material to form the spacer structure 430.

In particular, as shown in FIGS. 33 and 36, in some implementations of the present disclosure, forming the second opening 115 may include: forming second holes 103 penetrating through the stack structure 200′ in z-direction, where the plurality of second holes 103 are arranged with intervals in x-direction, and removing at least parts of the stack structure 200′ between second holes 103 adjacent in x-direction to form the second openings 115.

As an option, the second hole 103 may be formed in the same process as the first hole 101, the first channel hole 104, the second channel hole 105 and the third channel hole 106, where the third channel structure is formed in the third channel hole 106.

It is possible to remove partial stack structure 200′ and form the plurality of second holes 103 with for example dry etching process or a combination of dry etching process and wet etching process, or by implementing other manufacturing processes such as patterning processes including photolithography, cleaning and chemical mechanical polishing.

Optionally, as shown in FIGS. 33 and 34, in the direction intersecting z-direction (e.g., x-direction, y-direction), the size of the second hole 103 may be greater than or equal to the size m2 of the second channel hole 105.

As shown in FIGS. 33-36, after forming the plurality of second holes 103, it is possible to remove at least parts of the stack structure 200′ between second holes 103 adjacent in x-direction to form the second openings 115 with for example dry etching process or a combination of dry etching process and wet etching process, or by implementing other manufacturing processes such as patterning processes including photolithography, cleaning and chemical mechanical polishing.

As shown in FIGS. 36-37, after forming the second openings 115, it is possible to remove partial gate sacrificial layer 230 adjacent to the second openings 115 to form the separating void 116 with for example dry etching process or a combination of dry etching process and wet etching process, or by implementing other manufacturing processes such as patterning processes including photolithography, cleaning and chemical mechanical polishing.

After forming the separating void 116, as shown in FIGS. 37-38, it is possible to fill an insulating dielectric material in the communicated second openings 115 and the separating voids 116 with one or more film deposition processes to form the spacer structure 430.

As shown in FIGS. 38-39, the spacer structure 430 includes a plurality of isolation layers 4321, where the isolation layers 4321 may be stacked alternatively with first dielectric layers 210 in z-direction and disposed in the same layer as gate sacrificial layers 230. Optionally, the material for the isolation layer 4321 may include any suitable insulating dielectric material. For example, the isolation layers 4321 include an insulating dielectric material layer such as silicon oxide layer. As an option, the isolation layer 4321 may include the same insulating dielectric material layer as the first dielectric layers 210. In this case, there are still boundaries between the isolation layers 4321 and the first dielectric layers 210 since the forming processes for the isolation layers 4321 and the first dielectric layers 210 are different.

Furthermore, the spacer structure 430 further includes an isolation post 4322 extending in z-direction and including the same insulating dielectric material as the isolation layers 4321. Optionally, the isolation post 4322 is on a side of the second channel structure 320 in y-direction. The isolation post 4322 is formed by filling the second opening 115 (as shown in FIG. 37).

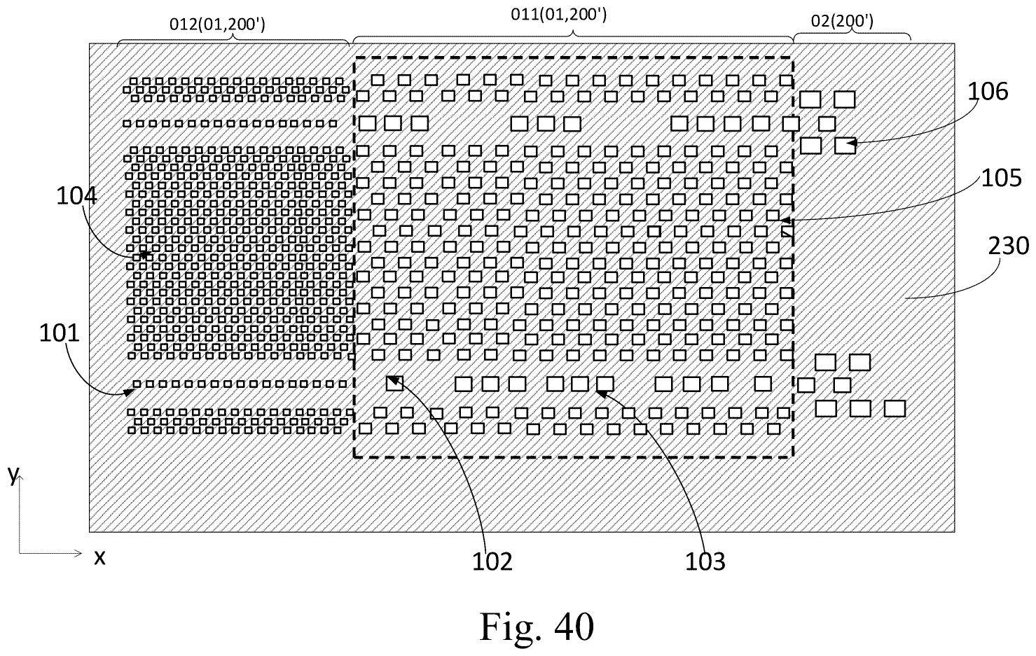

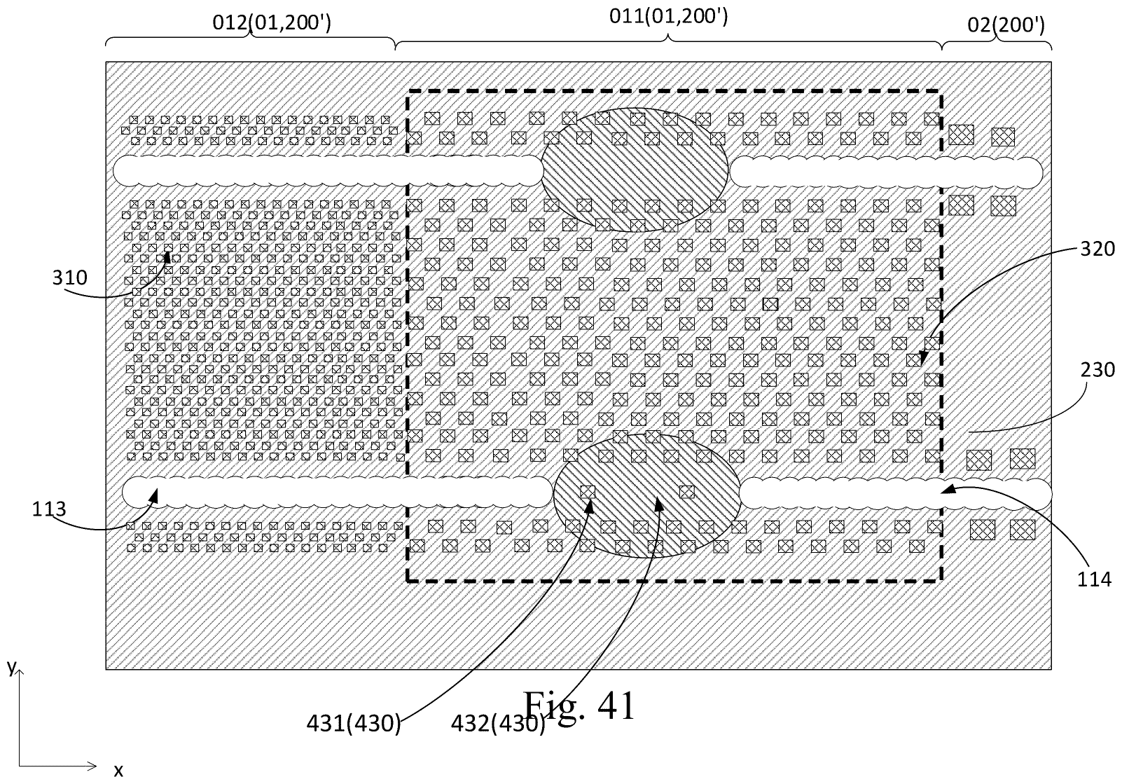

FIG. 40 is a top view of the structure after forming the first opening 102, according to yet another implementation of the present disclosure. FIG. 41 is a top view of the structure after forming the spacer structure 430, according to yet another implementation of the present disclosure.

As shown in FIGS. 10, 40 and 41, in some implementations of the present disclosure, the spacer structure 430 of the completed semiconductor device includes a first spacer structure 431 and a second spacer structure 432. In the present implementation, a plurality of second channel structures 320 and the spacer structure 430 are arranged in y-direction, and the size d2 of the second channel structure 320 is greater than the size d1 of the first channel structure 310, and in addition, the second spacer structure 432 may surround the first spacer structure 431.

As shown in FIGS. 40 and 41, in order to form the first spacer structure 431, it is possible to form the first opening 102 for containing the first spacer structure 431 in the process of forming the first hole 101. For example, the first opening 102 may be formed in the same process as the first hole 101, the second hole 103, the first channel hole 104, the second channel hole 105 and the third channel hole 106.

Optionally, as shown in FIGS. 34 and 40, in the direction intersecting z-direction (e.g., x-direction, y-direction), the size of the first opening 102 may be greater than or equal to the size m2 of the second channel hole 105.

As shown in FIGS. 35, 40 and 41, after forming the first opening 102, it is possible to form the first spacer structure 431 in the process of forming the first channel structure 310. For example, a functional layer 301 is formed in the first channel hole 104 and the first opening 102 and a channel layer 302 is formed on the surface of the functional layer 301, where parts of the functional layer 301 and the channel layer 302 that fill in the first opening 102 form the first spacer structure 431.

In other words, in order to simplify the fabrication process of the semiconductor device and reduce the fabrication costs of the semiconductor device, the first spacer structure 431 may be formed in the same process as the first channel structure 310, the second channel structure 320 and the third channel structure (the above-described first channel structure 310, the second channel structure 320 and the third channel structure will be referred to as channel structures hereinbelow). In particular, it is possible to form the functional layer 301 of the channel structure and the first layer 401 of the first spacer structure 431 with the same material, both of which may include an oxide-nitride-oxide (ONO) structure. However, in some other implementations, both the functional layer 301 and the first layer 401 may also have a structure different from ONO configuration. Furthermore, both the channel layer 302 and the second layer 402 may be fabricated from semiconductor material such as poly-crystalline silicon or single crystalline silicon and may have conductive impurities. In addition, the channel structure may further include a channel filling dielectric layer 303, and the first spacer structure 431 may further include a third layer 403, both of which may include an insulating dielectric material layer such as silicon oxide layer.

Therefore, according to the method of fabricating the semiconductor device provided in at least one implementation of the present disclosure, the semiconductor device includes a stack structure, a gate line isolation structure, a channel structure and a spacer structure, where the channel structure includes first channel structures and second channel structures, the spacer structure divides the gate line isolation structure into a first section and a second section arranged with an interval in the extension direction of the gate line isolation structure. This can reduce the case in which excess etch solution flows into other structures that have been formed in the semiconductor intermediate via gate line slits in the process of removing gate sacrificial layer with gate last process in fabricating the semiconductor device, thereby improving comprehensive performance of the semiconductor device.

Moreover, the spacer structure and the plurality of second channel structures are arranged along a direction intersecting both the stacking direction of the stack structure and the extension direction of the gate line isolation structure, and in the direction intersecting the stacking direction, the size of the second channel structure is configured to be greater than the size of the first channel structure, which may improve stress of the part of stack structure at which the spacer structure is located, reduce the cases in which topology of the channel structures shift, thereby improving the uniformity and consistency of the multiple channel structures and improving the comprehensive performance of semiconductor device.

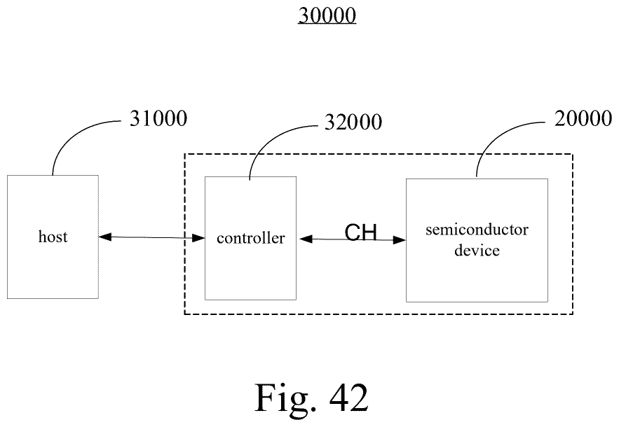

FIG. 42 is a structure diagram of a memory system 30000 according to an implementation of the present disclosure.

As shown in FIG. 42, at least one implementation according to yet another aspect of the present disclosure further provides a memory system 30000. The memory system 30000 may include a semiconductor device 20000 and a controller 32000. The semiconductor device 20000 may be the same as the semiconductor device described in any of the above implementations and will not be described any longer in the present disclosure. The semiconductor device 20000 may be a 2D semiconductor device or a 3D semiconductor device, or even a part of 2D semiconductor device or a part of 3D semiconductor device, and it will be described below with respect to a 3D semiconductor device as an example.

As an option, a 3D semiconductor device may include at least one of 3D NAND memory and 3D NOR memory.

The memory system 30000 may include a semiconductor device 20000 and a controller 32000. The semiconductor device 20000 may be the same as the semiconductor device described in any of the above implementations and will not be described any longer in the present disclosure. The controller 32000 may control the semiconductor device 20000 via a channel CH and the semiconductor device 20000 may execute operations based on the control by the controller 32000 in response to the request from the host 31000. The semiconductor device 20000 may receive a command CMD and an address ADDR from the controller 32000 through the channel CH and access regions selected from the memory cell array in response to the address. In other words, the semiconductor device 20000 may execute internal operations corresponding to the command on the regions selected by the address.

In some implementations, the 3D memory system may be implemented as multimedia cards such as universal flash storage (UFS) device, solid state hard disk (SSD), MMC, eMMC, RS-MMC and mini-MMC, secure digital cards such as SD, mini-SD and micro-SD, storage devices of Personal Computer Memory Card International Association (PCMCIA) type, storage devices of peripheral component interconnect (PCI) type, storage devices of PCI Express (PCI-E) type, compact flash (CF) cards, smart media cards or memory sticks etc. The memory system provided in the present disclosure is provided with the semiconductor device as provided in the present disclosure and therefore has the same beneficial effects as the semiconductor device, which will not be described any longer herein.

Although example methods of fabricating and structures of a semiconductor device have been described herein, it is appreciated that one or more features may be omitted from, substituted or added to the structure of the semiconductor device. Furthermore, materials illustrated for layers are only examples.

The description above is only for the purpose of explaining preferred implementations and technical principles of the present disclosure. It will be appreciated by those skilled in the art that the scope claimed by the present disclosure is not limited to technical solutions composed of selected combinations of the above-mentioned technical features, and instead will cover any other technical solutions composed of any combinations of the above-mentioned features and their equivalents without departing from the present technical concept. For example, technical solutions resulted from substitutions of the above-mentioned features by technical features of similar functions (but not limited to) disclosed in the present disclosure) still fall within the scope of the present disclosure.

What is claimed is:

1. A semiconductor device, comprising:
a stack structure comprising gate layers and first dielectric layers stacked alternatively in a first direction; and
a gate line isolation structure extending in the stack structure along a second direction intersecting the first direction and comprising a first section and a second section arranged with an interval in the second direction,
wherein the semiconductor device further comprises a first spacer structure and a second spacer structure, the first spacer structure and the second spacer structure are both located between the first section and the second section, and the second spacer structure surrounds the first spacer structure.

2. The semiconductor device of claim 1, wherein
the semiconductor device further comprises a channel structure extending in the stack structure in the first direction,
wherein the channel structure comprises a functional layer and a channel layer on a surface of the functional layer; and
the first spacer structure has a same layer structure as the channel structure.

3. The semiconductor device of claim 1, wherein
the second spacer structure comprises a plurality of isolation layers; and
the isolation layers and the first dielectric layers are stacked alternatively in the first direction and the isolation layer is disposed in a same layer as the gate layer.

4. The semiconductor device of claim 3, wherein
the second spacer structure further comprises an isolation post; and
the isolation post extends in the first direction and comprises a same insulating dielectric material as the isolation layer.

5. The semiconductor device of claim 1, wherein
the first spacer structure comprises a first separating structure and a second separating structure;
the first separating structure is closer to the first section in the second direction than the second separating structure; and
the second separating structure is closer to the second section in the second direction than the first separating structure.

6. The semiconductor device of claim 1, wherein a size of the first spacer structure in the second direction is greater than a size of the first spacer structure in a third direction, wherein the third direction intersects both the first direction and the second direction.

7. The semiconductor device of claim 1, wherein the first spacer structure comprises a plurality of post structures arranged with intervals in the second direction.

8. The semiconductor device of claim 1, wherein at least one surface of the gate line isolation structure comprises a curved surface including at least one of a concave surface and a convex surface.

9. The semiconductor device of claim 1, wherein
the stack structure comprises an array region and a connection region arranged in the second direction;
the gate layer comprises a first portion in the array region and a second portion in the connection region; and
a surface of the first portion facing the connection region comprises a curved surface including at least one of a concave surface and a convex surface.

10. The semiconductor device of claim 1, wherein
the stack structure further comprises a second dielectric layer disposed in a same layer as the gate layer; and
the first dielectric layer and the second dielectric layer comprise different insulating dielectric materials.

11. The semiconductor device of claim 1, wherein
a size of the first section or the second section in a third direction is less than or equal to a size of the first spacer structure in the third direction; and
the third direction intersects the first direction and the second direction.

12. The semiconductor device of claim 2, wherein an extension size D of the second spacer structure in a direction intersecting the first direction satisfies 400 nm≤D≤1500 nm.

13. The semiconductor device of claim 1, wherein
the stack structure comprises an array region and a connection region arranged in the second direction; and
the first spacer structure and the second spacer structure are both located in a first sub-region of the array region close to the connection region.

14. A semiconductor device, comprising:
a stack structure comprising gate layers and first dielectric layers stacked alternatively in a first direction;
a first channel structure and a second channel structure both extending in the stack structure in the first direction;
a gate line isolation structure extending in the stack structure along a second direction intersecting the first direction and comprising a first section and a second section arranged with an interval; and
a spacer structure between the first section and the second section, wherein
the spacer structure and a plurality of the second channel structures are arranged in a third direction, and the third direction intersects both the first direction and the second direction; and
a size of the second channel structure is greater than a size of the first channel structure in a direction intersecting the first direction.

15. The semiconductor device of claim 14, wherein
a part of the plurality of the second channel structures are located on a side of the spacer structure in the third direction, others of the plurality of the second channel structures are located in the spacer structure.

16. The semiconductor device of claim 14, wherein an extension size D of the spacer structure in a direction intersecting the first direction satisfies 400 nm≤D≤1500 nm.

17. The semiconductor device of claim 14, wherein
the spacer structure comprises a plurality of isolation layers; and
the isolation layers and the first dielectric layers are stacked alternatively in the first direction and the isolation layer is disposed in a same layer as the gate layer.

18. The semiconductor device of claim 17, wherein
the spacer structure further comprises an isolation post; and
the isolation post extends in the first direction and comprises a same insulating dielectric material as the isolation layer.

19. The semiconductor device of claim 14, wherein in a direction intersecting the first direction, a size d1 of the first channel structure and a size d2 of the second channel structure satisfy 1.1d1≤d2.

20. A memory system, comprising:
at least one semiconductor device, comprising:
a stack structure comprising gate layers and first dielectric layers stacked alternatively in a first direction;
a gate line isolation structure extending in the stack structure along a second direction intersecting the first direction and comprising a first section and a second section arranged with an interval in the second direction, wherein the semiconductor device further comprises a first spacer structure and a second spacer structure, the first spacer structure and the second spacer structure are both located between the first section, and the second section and the second spacer structure surrounds the first spacer structure; and
a controller coupled with the semiconductor device and configured to control the semiconductor device to store data.
